(19) United States
(12) Patent Application Publication
(10) Pub. No.: US 2026/0155801 A1
(43) Pub. Date: Jun. 4, 2026

(54) ELECTRO-OPTICAL MODULATOR DRIVER

(71) Applicant: NVIDIA Corporation, Santa Clara, CA (US)

(72) Inventors: Rasmus Jensen, Smoerum (DK); Ramses Pierco, Ghent (BE); Hao Li, Vancouver, WA (US); Arian Hashemi Talkhooncheh, Lubbock, TX (US)

(21) Appl. No.: 18/967,474

(22) Filed: Dec. 3, 2024

(51) Int. Cl. H03G 3/30; H03F 3/19

(52) U.S. Cl. CPC H03G 3/3042; H03F 3/19; H03F 2200/451

(57) ABSTRACT

A system includes a gain module, an optical module, and a feedback module. The gain module processes a first portion of an electrical signal to generate a first compensated portion of the electrical signal, the first portion of the electrical signal having a first frequency range. The optical module generates an optical signal based on a combination of the first compensated portion of the electrical signal and a second portion of the electrical signal having a second frequency range that is higher than the first frequency range. The feedback module provides, to the gain module, an electrical feedback signal based at least in part on a signal strength of the optical signal. The gain module updates the first compensated portion of the electrical signal based on the electrical feedback signal.

### TECHNICAL FIELD

At least one embodiment pertains to signal processing of an electrical signal for optical communications. For example, at least one embodiment pertains to technology for a closed-loop or partially-closed loop electro-optical modulator driver.

### BACKGROUND

Optical communication systems transmit an optical signal from a transmitter to a receiver via a communication channel or optical medium. Some optical components may be sensitive to fluctuations in physical conditions (e.g., temperature, etc.) of the transmitter. Certain transmission patterns may cause the temperature of sensitive optical components to exceed normal operating temperatures, which may result in unpredictable behavior of the sensitive optical component.

### BRIEF DESCRIPTION OF DRAWINGS

Various embodiments in accordance with aspects of the disclosure will be described with reference to the drawings, in which:

FIG. 1A illustrates an example communication system according to at least one example embodiment.

FIG. 1B illustrates an example partially-closed loop EOM driver according to at least one example embodiment.

FIG. 2 illustrates an example system implementing a partially-closed loop EOM driver according to at least one example embodiment.

FIG. 3A illustrates an example circuit for a partially-closed loop EOM driver according to at least one example embodiment.

FIG. 3B illustrates the example circuit for a partially-closed loop EOM driver according to at least one example embodiment.

FIG. 4 is an example flow diagram of an example method for using a partially-closed loop electro-optical modulator driver, according to at least one example embodiment.

FIG. 5A is a graphical representation of gain values for various signals in a closed-loop or partially-closed loop electro-optical modulator driver in a high bandwidth scenario, according to at least one example embodiment.

FIG. 5B is a circuit representation for a high-bandwidth scenario in a closed-loop or partially-closed loop electro-optical modulator driver.

FIG. 6A is a graphical representation of gain values for various signals in a closed-loop or partially-closed loop electro-optical modulator driver in a medium-bandwidth scenario, according to at least one example embodiment.

FIG. 6B is a circuit representation for a medium-bandwidth scenario in a closed-loop or partially-closed loop electro-optical modulator driver.

FIG. 7A is a graphical representation of gain values for various signals in a closed-loop or partially-closed loop electro-optical modulator driver in a low-bandwidth scenario, according to at least one example embodiment.

FIG. 7B is a circuit representation for a low-bandwidth scenario in a closed-loop or partially-closed loop electro-optical modulator driver.

FIG. 8 is an example flow diagram of an example method for controlling gain of an amplified signal in a closed-loop or partially-closed loop electro-optical modulator driver, according to at least one example embodiment.

FIG. 9 is a block diagram illustrating an exemplary computer system which may be a system with interconnected devices and components, a system-on-a-chip (SOC), or some combination thereof, according to aspects of the disclosure.

FIG. 10 is a block diagram illustrating an electronic device for utilizing a processor, according to aspects of the disclosure.

FIG. 11 is a block diagram of a processing system, according to aspects of the disclosure.

### DETAILED DESCRIPTION

Embodiments described herein relate to a closed-loop or partially-closed loop electro-optical modulator driver. Electro-optical modulators are sensitive to the spectral content of a modulation signal, which distorts transmission of wideband optical signals. This can be solved by pre-compensation of the signal, but this generally requires precise knowledge of the distortion mechanism in the electro-optical modulator. Moreover, these distortions can change over time due to external conditions such as temperature, input light power, and so on. In embodiments, a feedback loop is used to sense the optical output of the electro-optical modulator and compare it with a target signal to determine an error signal. An amplified version of the error signal may then be used to drive the electro-optical modulator in a manner that compensates for the distortions of the electro-optical modulator. In embodiments, when a signal bandwidth exceeds a bandwidth of the feedback loop, an open loop high-bandwidth driver can be added. To align the signal level of the closed loop driver with an open loop driver, a comparison of the target signal with the feedback signal, in the frequency spectrum where the open loop driver is dominant, may be used to regulate gain and/or phase of a feedback and/or reference path.

Some embodiments are directed to a system including a gain module to process a first portion of an electrical signal to generate a first compensated portion of the electrical signal, the first portion of the electrical signal having a first frequency range, an optical module to generate an optical signal based on a combination of the first compensated portion of the electrical signal and a second portion of the electrical signal having a second frequency range that is higher than the first frequency range, and a feedback module to provide, to the first gain module, an electrical feedback signal based at least in part on a signal strength of the optical signal, wherein the first gain module is to update the first compensated portion of the electrical signal based on the electrical feedback signal. Embodiments described herein may be used to pre-process an electrical signal to reduce the heat generated by an optical signal interacting with an electro-optical modulator, which may permit a wider range of signal frequencies to be reliably transmitted over an optical link.

Optical links are communication links that use optical fibers to transmit optical signals (e.g., data signals or data streams) between two points. For example, an optical transmitter (“transmitter”) may receive optical signals generated by one or more optical signal generators, and the transmitter may transmit optical signals to an optical receiver (“receiver”). In some implementations, an optical signal generator includes a laser. A transmitter may include a modulator that may encode data onto an optical signal using modulation, and the transmitter may transmit modulated optical signals to a receiver. The receiver may include a photodetector to detect optical signals (e.g., modulated optical signals) received from the transmitter, and may convert the optical signals into electrical signals that may be processed by an electronic device. Optical links may be used to transmit large amounts of data over long distances with minimal signal loss. Optical links may be used in a variety of applications that may utilizes the transmission of optical signals, such as switches, processing units (e.g., graphics processing units (GPUs), etc.

Various optical networking technologies may be used for transmitting multiple optical signals (e.g., data signals or data streams) over a single optical fiber within an optical link with little to no optical signal interference. Such optical networking technologies may increase the amount of data that may be transmitted via a single optical fiber, which may increase bandwidth efficiency and reduce the amount of infrastructure (e.g., hardware) needed for data communication.

One type of optical networking technology is time division multiplexing (TDM). In TDM, multiple optical signals (e.g., data signals or data streams) may be transmitted over a single optical fiber by assigning each optical signal a respective time slot, and transmitting an optical signal during its respective time slot. The time slots may be allocated to optical signals in a cyclic manner, in which each optical signal transmits a small amount of data during its assigned time slot. The time slots may be very short, such as on the order of microseconds, and the cycle is repeated many times per second to allow for rapid data transfer.

Another type of optical networking technology is frequency division multiplexing (FDM). In FDM, multiple optical signals (e.g., data signals or data streams) may be transmitted over a single optical fiber by assigning each optical signal a respective frequency band. More specifically, each optical signal may be modulated onto a respective carrier frequency to generate a respective modulated signal, and the modulated signals may be combined and transmitted by a receiver over a single optical fiber. At the receiver, the modulated signals may be separated using one or more filters (e.g., band-pass filters). More specifically, the one or more filters permit optical signals to pass through that meet one or more frequency specifications set by the one or more filters, while filtering out signals that do not meet the one or more frequency specifications. Accordingly, FDM may be used by optical links to simultaneously transmit multiple channels simultaneously over the same frequency band.

Yet another type of optical networking technology is wavelength division multiplexing (WDM). In WDM, multiple optical signals (e.g., data signals or data streams) having different wavelengths may be combined into a single optical signal and transmitted over a single optical fiber (e.g., simultaneous transmission of multiple wavelengths of light). More specifically, WDM techniques may generally involve combining and separating multiple optical signals having different wavelengths onto a single optical fiber. By doing so, WDM technology may allow for more data to be transmitted over an optical fiber and/or increase the capacity of the optical fiber.

Examples of WDM technology includes coarse wavelength division multiplexing (CWDM) and dense wavelength division multiplexing (DWDM). In CWDM, multiple optical signals (e.g., data signals or data streams) at different wavelengths are combined into a single optical signal and transmitted over a single optical fiber. The names CWDM and DWDM refer to the coarseness and denseness, respectively, of wavelength separation between wavelengths. More specifically, CWDM uses a coarser or wider wavelength separation than DWDM, which uses a denser or narrower wavelength separation. For example, wavelengths for CWDM may be separated by, e.g., about 80 nanometers (nm), while wavelengths for DWDM may be separated by, e.g., about 0.8 nm. The wider wavelength separation used in CWDM means that CWDM may support fewer channels and have lower power budgets than DWDM, and so CWDM may be used for shorter distances than DWDM, such as, e.g., up to about 80 kilometers (km). At the same time, CWDM uses less complex equipment and may use lower-cost optical components as compared to DWDM, which may make it a more cost-effective solution for applications that may not require denser wavelength separation.

Some optical link systems may implement at least one interferometer (e.g., in a transmitter and/or in a receiver) that functions as a demultiplexer or a multiplexer. In at least one embodiment, the interferometer may be used to implement WDM.

Some optical link systems may implement at least one electro-optical modulator (EOM). An EOM is an optical device which leverages the electro-optic effect of a material, in which a change in the refractive index of a material is induced by an applied electric signal, to modulate a beam of light (e.g., an optical signal). Materials that exhibit this electro-optic effect include, for example, lithium niobate (LiNbO₃), gallium arsenide (GaAs), indium phosphide (InP), etc. In at least one embodiment, the EOM may include one or more waveguides to guide light through a specific path to interact with the electro-optic material and produce the optical modulation. For example, the waveguide-based EOM may be a micro-ring EOM, a Mach-Zehnder EOM, or the like. In at least one embodiment, the EOM may use bulk crystals or thin films of electro-optic material, where the optical modulation is induced by applying an electric field across the material. For example, the non-waveguide-based EOM may be a Pockels Cells EOM or a Kerr Effect EOM.

An electro-optical modulator may be sensitive to changes in temperature. In at least one embodiment, the EOM and related components may include heaters that are operatively coupled to the EOM to perform thermal tuning. For example, a heater may include a set of heater pads connected to a wire. In some implementations, a heater is formed from tungsten (W). The heat generated by a heater operatively coupled to EOM may adjust the thermal properties of the EOM, which may alter the optical propagation of an optical signal through the EOM. For example, in an EOM with a waveguide, a heater coupled to the waveguide may adjust the thermal properties of the waveguide material, which may alter the rate of propagation of an optical signal through the waveguide. Heat tuning of the EOM may be performed by adjusting properties of the waveguides may include adjusting voltages of the heaters operatively coupled to the EOM.

Thermal tuning by heating pads or wires may effectively heat an EOM that is below a range of desired operational temperatures. However, using heating pads or wires to thermally tune an EOM that has a temperature above the range of desired operational temperatures is less effective. The temperature of the EOM may be influenced by various factors such as nearby electrical components, the ambient environment temperature, or electrical or optical signals interacting with the EOM. For example, a high-frequency optical signal may oscillate rapidly such that the optical signal does not significantly affect the temperature of the EOM. As the frequency of the optical signal approaches a steady-state direct current (DC) signal, the EOM is exposed to the optical signal for longer and longer periods of time which may result in a rise in the operating temperature of the EOM.

Some solutions to reduce the operating temperature of the EOM may include attenuating the amplitude of lower frequencies in the optical signal to reduce the amount of time the optical signal is interacting with the EOM. However, this approach may often have the result of effectively reducing the bandwidth of the optical signal based on which frequencies are attenuated. Other solutions may include active or passive cooling elements operatively coupled to the EOM that may be used to cool the EOM. However, these cooling elements may be bulky and impractical, and may still not sufficiently reduce the operating temperature of the EOM such that it may consistently transmit optical signals containing information in the lower frequencies. It may be appreciated that different solutions and/or implementations have different capabilities with regard to a lowest frequency that may be reliably communicated in an optical signal.

Generally, for the purposes of the present disclosure, “low frequency,” and “high frequency” can be related terms, with different relative values, depending on the desired implementation (e.g., the communication frequencies). In a first example, a “low frequency” can refer to a frequency between 0 hertz (Hz) and approximately 10 megahertz (MHz), and a “high frequency” can refer to a frequency above approximately 10 MHz. In a second example, a “low frequency can refer to a frequency between 0 hertz (Hz) and approximately 100 megahertz (MHz), and a “high frequency” can refer to a frequency above approximately 100 MHz. In a third example, a “low frequency” can refer to frequencies between 0 Hz and approximately 1 gigahertz (GHz), and a “high frequency” can refer to a frequency above approximately 1 GHz.

Aspects of the present disclosure may address the deficiencies above and other challenges by implementing a closed-loop or partially-closed loop electro-optical modulator (EOM) driver. An electrical input signal may be separated into a first portion and a second portion. The first portion may be modified by a gain module (e.g., “compensated”) and recombined with the second portion. The re-combined electrical signal may be converted to an optical signal. A portion of the resulting optical signal may be sampled and converted into an electrical feedback signal. The electrical feedback signal may be used as an input to the gain module used to amplify the first portion of the electrical signal. Thus, the first portion of the electrical signal may be modified by a gain module based on a closed loop while the second portion of the electrical signal may be modified by a second gain module based on an open loop in embodiments. In at least one embodiment, the second portion of the electrical signal may be modified by a second gain module. In such embodiments, the first gain module may be controlled in part by the electrical feedback signal (e.g., may be closed loop), while the second gain module may not be controlled by the electrical feedback signal (e.g., may be open loop).

More specifically, the portion of the electrical signal modified by the closed loop gain module may have a lower frequency than the portion of the electrical signal that is unmodified, or modified by an open loop gain module. By modifying the lower frequency portion of the electrical signal with the closed loop gain module, the heat generated by the resulting generated optical signal interfacing with the EOM will be reduced.

Advantages of the disclosure include, but are not limited to, an increase in bandwidth of an optical signal, an increased uniformity of signal strength across frequencies in the optical signal, a reduction in the thermal capacity of the optical signal, and a simplified heating and/or cooling mechanism for the EOM. For example, embodiments described herein may reduce the amount of heat introduced into the EOM environment, which may lead to simplified circuitry for maintaining the temperature of the EOM within a desired temperature range. The pre-processing for electrical signal described in embodiments herein achieves an optical signal having increased bandwidth and signal strength uniformity across optical frequencies with minimal power consumption and lower heat transmission from the optical signal to the EOM than systems that do not use a closed-loop or partially-closed loop gain module for lower frequencies.

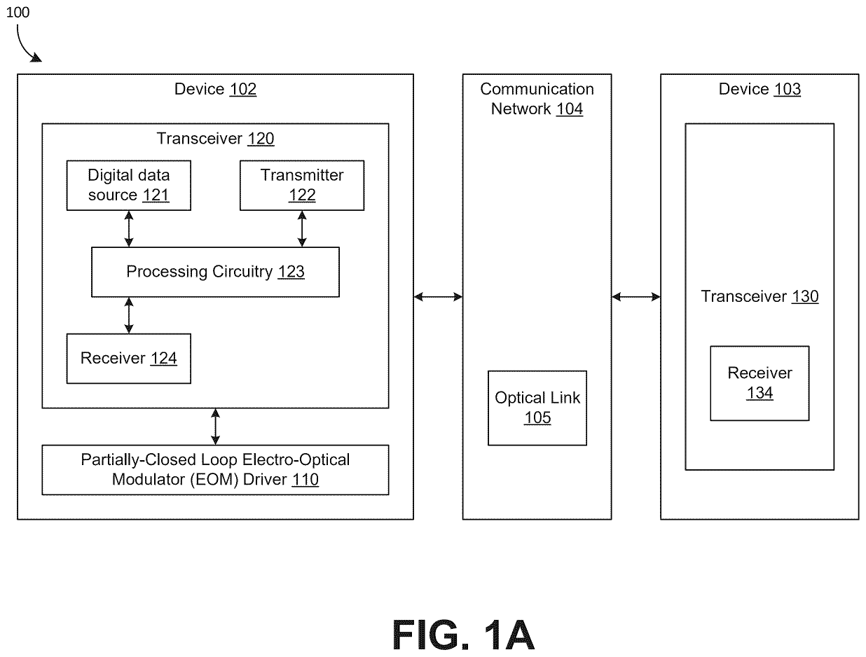

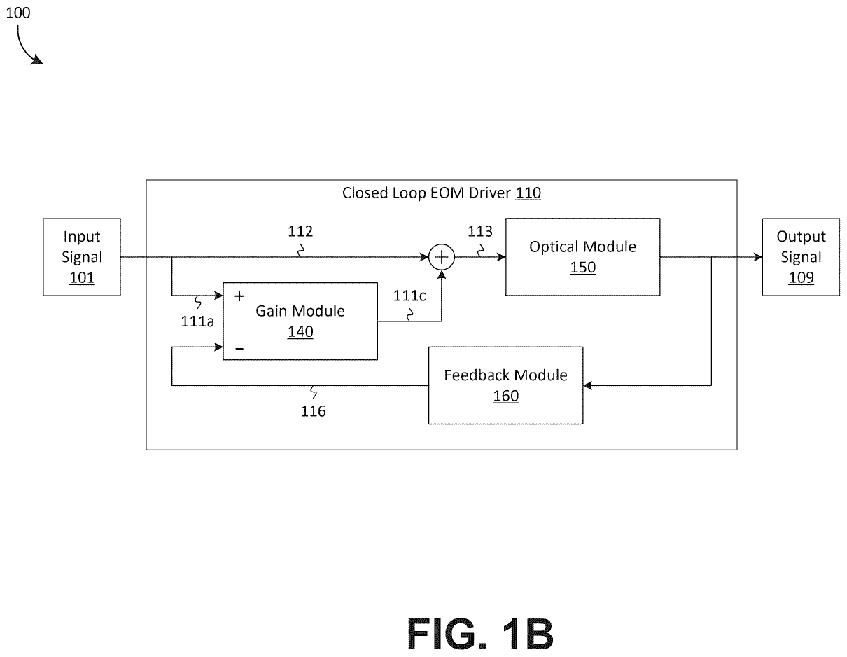

FIG. 1A illustrates an example communication system 100 according to at least one example embodiment. The communication system 100 includes a device 102 including a transceiver 120 and closed loop electro-optical modulator (EOM) driver 110, a communication network 104 including an optical link 105, and a device 103 including a transceiver 130.

In at least one embodiment, devices 102 and 103 are two end-point devices in a computing system, such as a central processing unit (CPU) or graphics processing unit (GPU). In at least one embodiment, devices 102 and 103 are two servers. In at least one example embodiment, devices 102 and 103 correspond to one or more of a Personal Computer (PC), a laptop, a tablet, a smartphone, a server, a collection of servers, or the like. In at least one embodiment, the devices 102 and 103 may correspond to any appropriate type of device that communicates with other devices connected to a common type of communication network 104. According to embodiments, the receiver 124, 134 of devices 102 or 103 may correspond to a GPU, a switch (e.g., a high-speed network switch), a network adapter, a CPU, a memory device, an input/output (I/O) device, other peripheral devices or components on a system-on-chip (SoC), or other devices and/or components at which a signal is received or measured, etc. As another specific but non-limiting example, the devices 102 and 103 may correspond to servers offering information resources, services, and/or applications to user devices, client devices, or other hosts in the communication system 100. In one example, devices 102 and 103 may correspond to network devices such as switches, network adapters, or data processing units (DPUs).

Examples of the communication network 104 that may be used to connect the devices 102 and 103 include an Internet Protocol (IP) network, an Ethernet network, an InfiniBand (IB) network, a Fibre Channel network, the Internet, a cellular communication network, a wireless communication network, a ground referenced signaling (GRS) link, combinations thereof (e.g., Fibre Channel over Ethernet), variants thereof, and/or the like. For example, the communication network 104 is a network that enables data transmission between the devices 102 and 103 using data signals (e.g., digital, optical, wireless signals). In one specific but non-limiting example, the communication network 104 is a network that enables data transmission between devices 102 and 103 using a communication link such as optical link 105.

The device 102 includes a transceiver 120 for sending and receiving signals, for example, data signals. The data signals may be digital or optical signals modulated with data or other suitable signals for carrying data. The transceiver 120 may include a digital data source 121, a transmitter 122, a receiver 124, and processing circuitry 123 that controls the transceiver 120. The digital data source 121 may include suitable hardware and/or software for outputting data in a digital format (e.g., in binary code and/or thermometer code). The digital data output by the digital data source 121 may be retrieved from memory (not illustrated) or generated according to input (e.g., user input). The transceiver 120 or selected elements of the transceiver 120 may take the form of a pluggable card or controller for the device 102. For example, the transceiver 120 or selected elements of the transceiver 120 may be implemented on a network interface card (NIC).

The transmitter 122 includes suitable software and/or hardware for receiving digital data from the digital data source 121 and outputting data signals according to the digital data for transmission over the communication network 104 to a receiver 134 of device 103.

The receiver 124 of device 102 or the receiver 134 of device 103 may include suitable hardware and/or software for receiving signals, such as data signals from the communication network 104. For example, the receiver 124 and/or receiver 134 may include components for receiving optical signals.

The processing circuitry 123 may include software, hardware, or a combination thereof. For example, the processing circuitry 123 may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In at least one embodiment, the memory and processor may be integrated into a common device (e.g., a microprocessor may include integrated memory). Additionally, or alternatively, the processing circuitry 123 may include hardware, such as an application-specific integrated circuit (ASIC). Other non-limiting examples of the processing circuitry 123 include an Integrated Circuit (IC) chip, a Central Processing Unit (CPU), a General Processing Unit (GPU), a microprocessor, a Field Programmable Gate Array (FPGA), a collection of logic gates or transistors, resistors, capacitors, inductors, diodes, or the like. Some or all of the processing circuitry 123 may be provided on a Printed Circuit Board (PCB) or collection of PCBs. It should be appreciated that any appropriate type of electrical component or collection of electrical components may be suitable for inclusion in the processing circuitry 123. The processing circuitry 123 may send and/or receive signals to and/or from other elements of the transceiver 120 to control the overall operation of the transceiver 120. In at least one embodiment, the processing circuitry 123 may facilitate a method to implement a closed-loop or partially-closed loop electro-optical modulator (EOM) driver, as described below.

The closed-loop or partially closed-loop EOM driver 110 may include software, hardware, or a combination thereof. For example, the closed-loop or partially closed-loop EOM driver 110 may include a memory including executable instructions and a processor (e.g., a microprocessor) that executes the instructions on the memory. The memory may correspond to any suitable type of memory device or collection of memory devices configured to store instructions, as described above. Additionally, or alternatively, the closed-loop or partially closed-loop EOM driver may include hardware such as an ASIC, an IC chip, CPU, GPU, microprocessor, FPGA, or collection of logic gates or transistors, resistors, capacitors, inductors, diodes, or the like. It should be appreciated that any appropriate type of electrical component or collection of electrical components may be suitable for inclusion in the closed-loop or partially closed-loop EOM driver 110. The closed-loop or partially closed-loop EOM driver 110 may send and/or receive signals to and/or from other elements of the device 102 such as the transceiver 120 to control the overall operation of the device 102. In at least one embodiment, some or all of the closed-loop or partially closed-loop EOM driver 110 may be implemented in the transceiver 120 as part of the processing circuitry 123 (not illustrated). Additional details of the structure of the closed-loop or partially closed-loop EOM driver 110 are discussed in more detail below with reference to the figures.

The device 103 may include a transceiver 130 for sending and receiving signals, for example, data signals over a communication link 105 of the communication network 104. The same or similar structure of the transceiver 120 may be applied to transceiver 130, and thus, the structure of transceiver 130 is not described separately.

Although not explicitly shown, it should be appreciated that devices 102 and 103 and the transceivers 120 and 130 may include other processing devices, storage devices, and/or communication interfaces generally associated with computing tasks, such as sending and receiving data.

FIG. 1B illustrates an example closed-loop or partially closed-loop EOM driver 110 (referred to simply as a closed-loop EOM driver for simplicity) according to at least one example embodiment. The closed-loop EOM driver 110 includes a gain module 140, an optical module 150, and a feedback module 160. The closed-loop EOM driver 110 may interface with the device 102 of FIG. 1A by way of the illustrative input signal 101 and output signal 109 in embodiments.

The input signal 101 (e.g., an input electrical signal) is separated at the closed-loop EOM driver 110 into a first signal 111a (e.g., a first portion of the electrical signal) and a second signal 112 (e.g., a second portion of the electrical signal). Various methods or systems may be used to separate the input signal 101 into the first signal 111a and the second signal 112, including for example, passive or active filters, signal processing techniques using a digital signal processor (DSP), or the like.

The first signal 111a is input to the gain module 140. The gain module 140 modifies the first signal 111a and outputs a first compensated signal 111c (e.g., first compensated portion of the electrical signal). The gain module 140 may accept one or more signal inputs and generate an output based on the one or more signal inputs. In at least one embodiment, the gain module 140 accepts the first compensated signal 111c and an electrical feedback signal 116 (further described below) as inputs to generate the first compensated signal 111c.

The first compensated signal 111c and the second signal 112 are combined to form the combined signal 113. Various methods or systems may be used to combine the first compensated signal 111c and the second signal 112, including for example, summing components, active or passive mixer circuitry, transformers, signal processing techniques using a DSP, or the like. While not illustrated in FIG. 1B, additional processing elements (such as circuitry or logic) may be applied to the second signal 112 prior to combining the second signal 112 with the first compensated signal 111c. For example, and in at least one embodiment, processing elements for the second signal 112 may include circuitry for delaying the second signal 112.

The combined signal 113 is input to the optical module 150. The optical module 150 receives an electrical signal and outputs an optical signal 114. The optical module 150 may include various components for converting an electrical signal to an optical signal. For example, components may include light emitting elements (e.g., Light Emitting Diodes (LEDs), Light Amplification by Stimulated Emission of Radiation (LASER or laser) devices, etc.), optical lenses or mirrors, modulators (e.g., electro-optical modulators), resonators (e.g., electro-optical resonators), or the like. In at least one embodiment, the optical module 150 outputs the output signal 109 which is detected by the feedback module 160 without modifying the output signal 109. In at least one embodiment, detection by the feedback module 160 of the output signal 109 modifies the output signal 109.

The output signal 109 is input to the feedback module 160. The feedback module 160 outputs an electrical feedback signal 116. The feedback module 160 may include various components for converting an optical signal to an electrical signal. For example, components may include light-detecting elements (e.g., photodiodes), passive electronics, analog processing elements, an analog-to-digital converter (ADC), or the like.

The electrical feedback signal 116 is input to the gain module 140. The electrical feedback signal 116 may be used to control the gain module 140. In at least some embodiments, the feedback module 160 includes a gain control module (not illustrated) for modifying the electrical feedback signal 116.

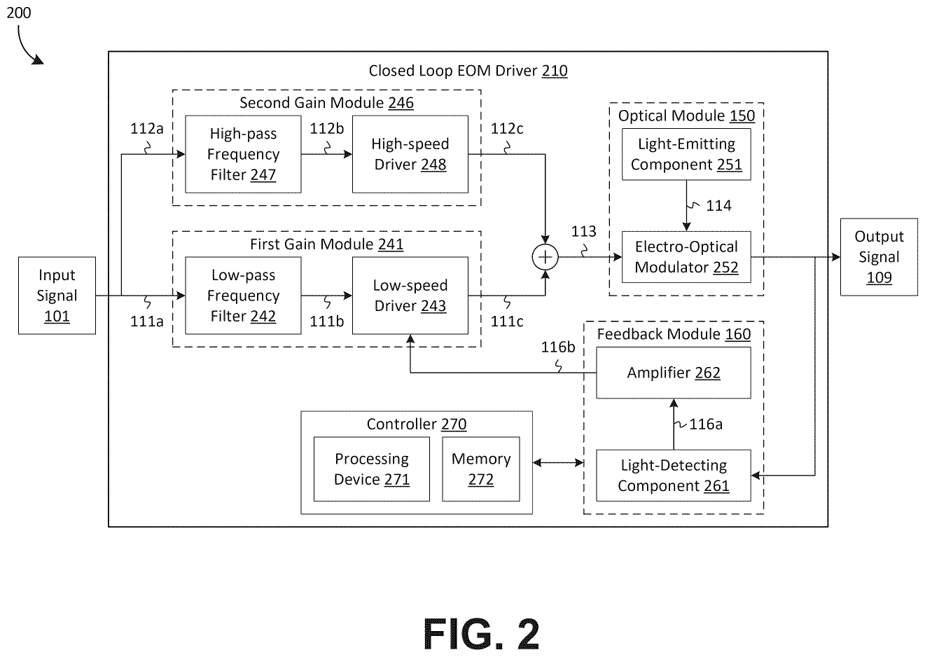

FIG. 2 illustrates an example system 200 implementing a closed-loop EOM driver 210 according to at least one example embodiment. The closed-loop EOM driver 210 includes a first gain module 241, a second gain module 246, an optical module 150, a feedback module 160, and a controller 270. The closed-loop EOM driver 210 may interface with the device 102 of FIG. 1A (not illustrated) by way of the illustrative input signal 101 and output signal 109.

The input signal 101 is separated at the closed loop EOM driver 210 into a first signal 111a and a second signal 112a. As described above, various methods or systems may be used to separate the input signal 101 into the first signal 111a and the second signal 112, including for example, passive or active filters, signal processing techniques using a digital signal processor (DSP), or the like. In at least one embodiment, the input signal 101 is coupled directly to the first gain module 241 and the second gain module 246. In FIG. 2, first signal 111a and second signal 112a are illustrated as distinct from input signal 101 for clarity of explanation. In at least one embodiment, the first signal 111a and the second signal 112a are not separated prior to being input to the first gain module 241 and the second gain module 246 respectively. Rather, the first gain module 241 and the second gain module 246 each receive the input signal 101 and extract out the first signal and the second signal respectively.

The first gain module 241 includes a low-pass frequency filter 242 and a low-speed driver 243. In at least one embodiment a low-speed driver refers to a signal driver that drives a low-speed (e.g., low-frequency) signal. In at least one embodiment, the low-speed driver includes a low-pass filter. The first gain module 241 receives first signal 111a (or input signal 101 as described above) at the low-pass frequency filter 242. The low-pass frequency filter 242 removes frequencies above a predetermined cut-off frequency. The low-pass frequency filter 242 may be one or more of an analog filter, a digital filter, a passive filter, or an active filter. In at least one embodiment, as described above the predetermined cut-off frequency may be approximately between 10 KHz and 1 MHz. The low-pass frequency filter 242 produces an output of the first filtered signal 111b. The first filtered signal 111b is input to the low-speed driver 243.

The low-speed driver 243 produces a first compensated signal 111c as an output. In at least one embodiment, the low-speed driver 243 amplifies the first filtered signal 111b to generate the first compensated signal 111c by a first gain value. In at least one embodiment, the first gain value is predetermined. In at least one embodiment, the first gain value is variable. In at least one embodiment, the first gain value may be adjusted by an output signal from the feedback module 160 (e.g., electrical feedback signal 116b, described below). The first gain module may include additional filters, elements and/or signal processing logic (not illustrated) to modify the first signal 111a (or the input signal 101 as described above) to produce a first compensated signal 111c.

The second gain module 246 includes a high-pass frequency filter 247 and a high-speed driver 248. In at least one embodiment a high-speed driver refers to a signal driver that drives a high-speed (e.g., high-frequency) signal. In at least one embodiment, the high-speed driver includes a high-pass filter. The second gain module 246 receives second signal 112a (or input signal 101 as described above) at the high-pass frequency filter 247. The high-pass frequency filter 247 removes frequencies below a predetermined cut-off frequency. The high-pass frequency filter 247 may be one or more of an analog filter, a digital filter, a passive filter, or an active filter. In at least one embodiment, as described above the predetermined cut-off frequency may be approximately between 10 KHz and 1 MHz. In at least one embodiment, the cut-off frequency for the high-pass frequency filter 247 is the same as, or similar to, the cut-off frequency for the low-pass frequency filter 242 of the first gain module 241. The high-pass frequency filter 247 produces an output of the second filtered signal 112b. The second filtered signal 112b is input to the high-speed driver 248.

The high-speed driver 248 produces a second compensated signal 112c as an output. In at least one embodiment, the high-speed driver 248 amplifies the second filtered signal 112b to generate the second compensated signal 112c by a second gain value. In at least one embodiment, the second gain value is predetermined. In at least one embodiment, the gain value is determined during production and/or manufacture of the closed-loop EOM driver 210. The gain value may be selected to comply with one or more requirements for a system that includes the closed loop EOM driver 210. The second gain module may include additional filters, elements and/or signal processing logic (not illustrated) to modify the second signal 112a (or the input signal 101 as described above) to produce a second compensated signal 112c.

The first compensated signal 111c and the second compensated signal 112c are combined to form the combined signal 113. As described above, various methods or systems may be used to combine the first compensated signal 111c and the second signal 112, including for example, summing components, active or passive mixer circuitry, transformers, signal processing techniques using a DSP, or the like. In at least one embodiment, the first gain module 241 and/or the second gain module 246 may include one or more delay components. The delay components may be used to synchronize the phase of the first compensated signal 111c with the phase of the second compensated signal 112c. In at least one embodiment, the delay components include one or more of buffers, registers, or the like.

The combined signal 113 is input to the optical module 150. The optical module 150 outputs th an optical signal (e.g., output signal 109). The optical module 150 includes a light-emitting component 251 and an electro-optical modulator 252. In at least one embodiment, the light-emitting component 251 includes at least one of an LED, a laser device, or the like. In at least one embodiment, the electro-optical modulator 252 is a micro-ring modulator (MRMOD). For example, the electro-optical modulator 252 may include a ring resonator, such as a micro-ring resonator.

The combined signal 113 may be received as input to the electro-optical modulator 252 of the optical module 150. In at least one embodiment, the combined signal 113 causes the electro-optical modulator 252 to modulate an initial optical signal 114 received from a light-emitting component 251 of the optical module 150. In at least one embodiment, the light-emitting component 251 is external to the optical module 150. In at least one embodiment, the light emitting component 251 is external to the closed-loop EOM driver 210. In at least one embodiment, the combined signal 113 is received at the light-emitting component 251, which modulates the combined signal 113 into an optical signal (e.g., the output signal 109).

In at least one embodiment, the combined signal 113 is received at the electro-optical modulator 252. The initial optical signal 114 may be received from an optical signal generating component outside of the closed loop EOM driver 210. The combined signal 113 acts as a control signal for the electro-optical modulator 252. The electro-optical modulator 252 modulates the initial optical signal 114 based on the combined signal 113 to generate the output signal 109. The optical module 150 may include additional electrical or optical filters, elements, and/or signal processing logic (not illustrated) to convert an electrical signal input (e.g., the combined signal 113) into an optical signal (e.g., the output signal 109).

In at least one embodiment, the optical module 150 outputs the output signal 109 which is detected by the feedback module 160 without modifying the output signal 109. In at least one embodiment, detection by the feedback module 160 of the output signal 109 modifies the output signal 109.

The output signal 109 is input to the feedback module 160. The feedback module 160 outputs an electrical feedback signal 116b. The feedback module 160 includes a light-detecting component 261 and an amplifier 262. In at least one embodiment, the light-detecting component 261 is a photodiode. The light-detecting component 261 produces a detecting signal 116a. In at least one embodiment, the detecting signal 116a has a constant voltage with a variable current. In at least one embodiment, the detecting signal 116a has a constant current with a variable voltage.

The detecting signal 116a is input to the amplifier 262. The amplifier 262 may modify the detecting signal 116a to generate the electrical feedback signal 116b. In at least one embodiment, the amplifier 262 may modify the detecting signal 116a based on a gain value of the amplifier 262. In at least one embodiment, the gain value of the amplifier is variable. The gain value may be changed based on an algorithm. The algorithm may change the variable gain value of the amplifier based on a power level of the output signal 109. In at least one embodiment, the variable gain value of the amplifier is determined by the controller 270. In at least one embodiment, the algorithm, or steps to perform the algorithm to change the variable gain value of the amplifier are performed by the controller 270.

The controller 270 includes a processing device 271 and memory 272. In at least one embodiment, one or more functions of the controller 270 are performed by other elements of the closed-loop EOM driver 210, or a device containing the closed-loop EOM driver 210, such as device 102 of FIG. 1A (not illustrated). For example, one or more portions of the controller 270 may be implemented as part of the processing circuitry 123 of the transceiver 120, or a global controller or processing component of the device 102 (not illustrated).

Returning to FIG. 2, the electrical feedback signal 116b is input to the gain module 140. The electrical feedback signal 116b may be used to control the gain module 140. In at least some embodiments, the feedback module 160 includes a gain control module (not illustrated) for modifying the electrical feedback signal 116b.

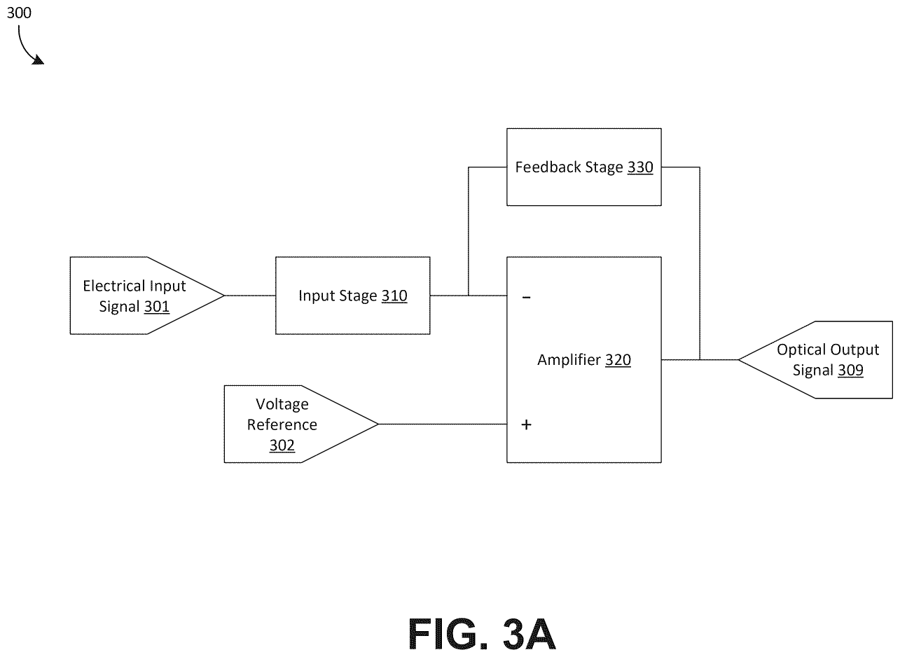

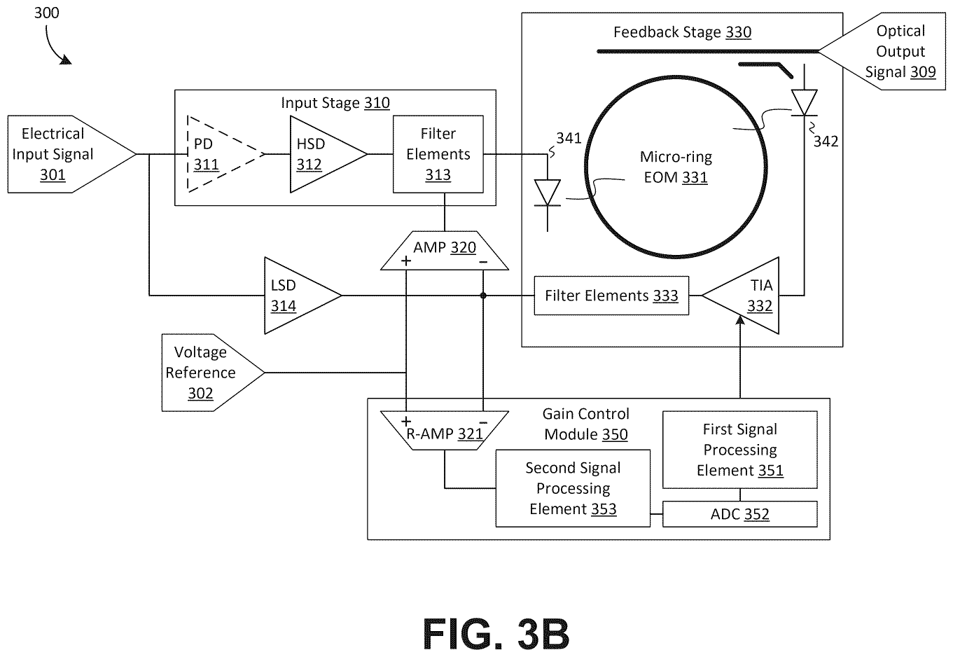

FIG. 3A illustrates an example circuit 300 for a partially-closed loop EOM driver according to at least one example embodiment. The circuit 300 includes an electrical input signal 301, a voltage reference 302, an optical output signal 309, an input stage 310, an amplifier 320, and a feedback stage 330.

The electrical input signal 301 may be an electrical signal that includes multiple frequencies. For example, and in at least one embodiment, the electrical signal may include information represented by frequencies spanning from 0 Hz through approximately 50 GHz. In another example, the electrical signal may include information represented by frequencies spanning from 0 Hz through approximately 100 GHz, or even greater frequencies.

The input stage 310 may include various passive and/or active elements used to pre-process the electrical input signal for the amplifier 320. In at least one embodiment, the input stage 310 includes driver circuitry for at least a portion of the electrical input signal 301. In at least one embodiment, the input stage includes filter circuitry for at least a portion of the electrical input signal 301.

The amplifier 320 receives a first input (illustrated in FIG. 3A as the negative input) that is a combination of an electrical signal output from the input stage 310 and an electrical signal output from the feedback stage 330. Using a second input (illustrated in FIG. 3A as the positive input) as a voltage reference 302, the amplifier 320 amplifies the combined electrical signal received at the first input to produce the optical output signal 309. In at least one embodiment, the amplifier 320 includes an electro-optical element that generates an optical signal. In an alternative embodiment, the amplifier 320 produces an electrical signal output that is converted by an electro-optical element (not illustrated) into the optical output signal 309.

The feedback stage 330 may include various passive and/or active electrical and/or optical elements used to process the output from the amplifier 320. In at least one embodiment, the feedback stage 330 includes amplifier circuitry for at least a portion of an optical signal (e.g., optical output signal 309). In at least one embodiment, the feedback stage 330 includes filter circuitry for an electrical signal generated from the at least portion of the optical signal.

The gain of the amplifier 320 may be determined by values associated with each of the input stage 310 and the feedback stage 330. For example, and by way of simplistic comparison, it may be appreciated that the circuit 300 resembles an operational amplifier with a closed gain loop. It may similarly be appreciated that the gain (“A”) of the amplifier 320 may be approximated by the equation:

$$A = \frac{{Z}_{feedback}}{{Z}_{input}}$$

where Z_{feedback} reflects the impedance value of the input stage 310 and Z_{feedback} reflects the impedance value of the feedback stage 330. In at least one embodiment, the amplifier 320 may have an transconductance value (gₘ) that affects the relationship between the input to the amplifier (e.g., voltage-in, or Vᵢₙ) and the output from the amplifier (e.g., voltage-out or Vₒᵤₜ), which may be approximated by the equation: Vₒᵤₜ=Vᵢₙ×A×gₘ.

In at least one embodiment, the gain of the amplifier 320 is variable. In at least one embodiment, values associated with the feedback stage 330 (or elements of the feedback stage 330) may be adjusted to change the effective gain of the amplifier 320. As used herein, effective gain may refer to the value G_{effective} approximated by: G_{effective}=A×gₘ.

FIG. 3B illustrates the example circuit 300 for a closed-loop or partially-closed loop EOM driver according to at least one example embodiment. The circuit 300 includes an electrical input signal 301, a voltage reference 302, an optical output signal 309, an input stage 310, a low-speed driver (LSD) 314, an amplifier (AMP) 320, a feedback stage 330, and a gain control module 350. The electrical input signal 301, the amplifier 320, and the optical output signal 309 are generally described above with reference to FIG. 3A.

Returning to FIG. 3B, the input stage 310 includes a pre-driver (PD) 311, a high-speed driver (HSD) 312, and filter elements 313.

The pre-driver 311 is an optional component (as indicated by the dashed lines) to preprocess a portion of the signal that is provided to the high-speed driver 312. In at least one embodiment, the pre-driver 311 may include a high-pass frequency filter to condition the signal for the high-speed driver 312. In at least one embodiment, the pre-driver 311 may delay a portion of the signal that is provided to the high-speed driver 312. The pre-driver 311 may have additional elements that may condition the electrical input signal 301 for processing at the high-speed driver 312. In at least one embodiment, processing performed at the pre-driver 311 may include one or more of power or signal amplification, impedance matching, level-shifting, or the like.

The high-speed driver 312 may process a portion of the electrical input signal 301. In at least one embodiment, the high-speed driver 312 may include a high-pass frequency filter that removes low-frequency portions of the electrical input signal 301, as described above. For example, and in at least one embodiment, the high-speed driver 312 may process a high-frequency portion of the electrical input signal 301. The high-speed driver 312 may have additional elements that may condition, or otherwise process the electrical input signal 301 for processing at the high-speed driver 312. In at least one embodiment, processing performed at the high-speed driver 312 includes one or more of power or signal amplification, impedance matching, level-shifting, or the like.

The filter elements 313 may include passive and/or active components for conditioning the output of the high-speed driver 312 for the amplifier 320. In at least one embodiment, the filter elements 313 may be used to set or adjust the impedance value of the input stage 310. In at least one embodiment, the input stage 310 includes a capacitor connected in series with the high-speed driver 312. In at least one embodiment, the input stage 310 includes a resistor coupled between an output of the high-speed driver and a voltage potential.

The low-speed driver 314 may process a portion of the electrical input signal 301. In at least one embodiment, the low-speed driver 314 may include a low-pass frequency filter that removes high-frequency portions of the electrical input signal 301, as described above. For example, and in at least one embodiment, the low-speed driver 314 may process a low-frequency portion of the electrical input signal 301. The low-speed driver 314 may have additional elements that may condition, or otherwise process, the electrical input signal 301 for processing at the low-speed driver 314. In at least one embodiment, processing performed at the low-speed driver 314 includes one or more of power and/or signal amplification, impedance matching, level-shifting, or the like.

The amplifier 320 may modify an input signal (e.g., received from input stage 310) based on intrinsic properties related to the physical construction of the amplifier 320, as described above with reference to FIG. 3A. For example, and in at least one embodiment, the amplifier 320 may be associated with a transconductance value (gₘ). The value of gₘ and the values of elements in the input stage 310 may determine the pole of the amplifier 320. As used herein, an amplifier pole represents a frequency point at which the gain, or response, of the amplifier decreases by approximately-3 decibels (dB) (e.g., approximately half the original value) in a frequency response. In at least one embodiment, the gain of the amplifier 320 may be in part based on the transconductance value gₘ of the amplifier 320, resistance values of elements in the input stage 310 and/or capacitance values of elements in the input stage 310.

The feedback stage 330 includes a micro-ring EOM 331, transimpedance amplifier (TIA) 332, and filter elements 333. While light-emitting component 341 and light-detecting component 342 are illustrated as included in the feedback stage 330 in FIG. 3B, this is for case of explanation and organization in the figure. In at least one embodiment, the feedback stage 330 includes at least one of the light-emitting component 341 or the light-detecting component 342.

The light-emitting component 341 may optically couple with the micro-ring EOM 331. In at least one embodiment, the light-emitting component 341 converts an electrical signal received from the input stage 310 to an optical signal that may be received by the micro-ring EOM 331. In another embodiment, the light-emitting component 341 provides the micro-ring EOM 331 with an optical signal, and an electrical signal from the input stage 310 is used to control how the micro-ring EOM 331 modulates the optical signal. As described above, the light-emitting component may include one or more of an LED, a laser device, or the like. The light-detecting component 342 may optically couple with the micro-ring EOM 331. In at least one embodiment, the light-detecting component 342 detects or receives a portion of the optical output signal 309. The light-detecting component 342 may convert the portion of the optical output signal 309 into an electrical signal. In at least one embodiment, the electrical signal produced by the light-detecting component 342 may be a variable current signal.

The micro-ring EOM 331, as described above, is an optical device which leverages the electro-optic effect of a material. When an electrical signal is applied to the material, the electro-optic effect that results is a change in the refractive index of the material. The micro-ring EOM 331 may be used to encode data onto an optical signal by activating the electro-optical effect of the micro-ring EOM at the cadence of an input electrical signal.

The transimpedance amplifier 332 receives a signal from the light-detecting component 342. In at least one embodiment, the transimpedance amplifier 332 may convert a current signal received from the light-detecting component 342 into a voltage signal. In at least one embodiment, the gain of the transimpedance amplifier is variable, and may be modified by the gain control module 350, described below.

The gain control module 350 includes a first signal processing element 351, an analog-to-digital converter “ADC” 342, a second signal processing element 353, and a replication amplifier “R-AMP” 321. In at least one embodiment, the gain control module 350 is controlled by a controller, such as controller 270 of FIG. 2. In at least one embodiment, one or more of the first signal processing element 351 or the second signal processing element 353 may be a passive or active signal processing element.

For example, and in at least one embodiment, the first signal processing element 351 is an active component that samples the analog signal received from the light-detecting component. The signal may be sampled based on an algorithm, such as a maximization algorithm (e.g., identifying highest power/current/voltage values of the signal), a minimization algorithm (e.g., identifying lowest power/current/voltage values of the signal), or the like. In at least one embodiment, the sampling performed by the first signal processing element 351 is actively controlled (not illustrated), such as by controller 270 of FIG. 2, and may be modified in real-time or at boot/run time of the gain control module.

In another example, and in at least one embodiment, the second signal processing element 353 is an active element that may sample and/or further process the digital signal received from the ADC 352. In at least one embodiment, the second signal processing element 353 may perform one or more of digital filtering, pulse-width modulation, down-sampling, digital rectification, or signal operations, such as calculating a Root Mean Square (RMS) value for the signal.

The replication amplifier 321 may receive a signal from the second signal processing element 353. In at least one embodiment, the replication amplifier 321 has the same physical characteristics of the amplifier 320. The outputs of each amplifier are connected, and each amplifier receives the same voltage reference value. In this closed-loop configuration, the replication amplifier 321 and the amplifier 320 may work together to boost the signal received from the low-speed driver 314 by a gain value managed by the gain control module 350.

This configuration of the closed-loop amplifiers (e.g., amplifier 320 and replication amplifier 321) allows one portion of an electrical signal (e.g., as illustrated, a lower-frequency portion of this electrical signal) to be amplified more or less than another portion of the electrical signal. The output from the replication amplifier 321 allows the first signal processing unit 351 and the second signal processing unit 353 to determine a gain value (e.g. a desired gain value) for the gain control module 350. In at least one embodiment, the lower-frequency portion of the electrical input signal 301 is amplified more than the higher-frequency portion of the electrical input signal 301. This in turn may produce an optical output having a more uniform signal gain across multiple frequencies. In some embodiments, the first signal processing element 351 identifies low-frequency levels in a signal, and the second processing element 353 identifies high-frequency levels in the signal, which can be compared by the gain control module 350 to determine the gain value for the TIA 332. In some embodiments, the first signal processing element 351 identifies high-frequency levels in a signal and the second processing element 353 identifies low-frequency levels in the signal, which can be compared by the gain control module 350 to determine the gain value for the TIA 332.

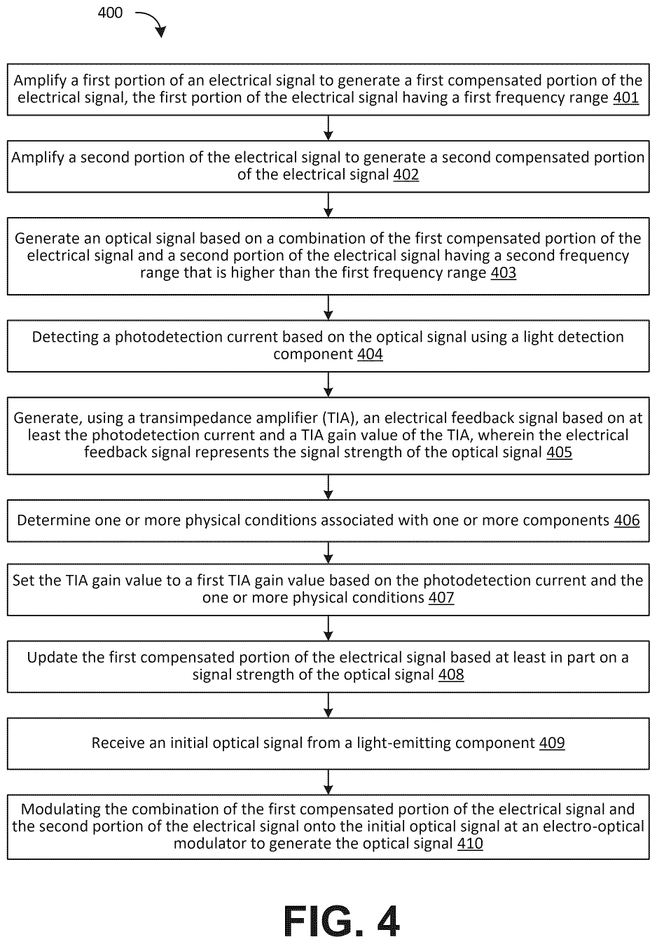

FIG. 4 is an example flow diagram of an example method 400 for using a closed-loop or partially-closed loop electro-optical modulator driver, according to at least one example embodiment. The method 400 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In at least one embodiment, one or more operations of the method 400 are performed by the processing circuitry 123 of FIG. 1. In at least one embodiment, one or more operations of the method 400 are performed by the closed-loop EOM driver 110 of FIG. 1. In at least one embodiment, one or more operations of the method 400 are performed by passive and/or active circuit elements. In at least one embodiment, one or more operations of the method 400 are performed by circuit logic elements (such as by the controller 270 of FIG. 2). Although shown in a particular sequence or order, unless otherwise specified, the order of the processes may be modified. Thus, the illustrated embodiments should be understood only as examples, and the illustrated processes may be performed in a different order, and some processes may be performed in parallel. Additionally, one or more processes may be omitted in various embodiments. Thus, not all processes are required in every embodiment. Other process flows are possible.

At operation 401, processing logic performing the method 400 amplifies a first portion of an electrical signal to generate a first compensated portion of the electrical signal. The first portion of the electrical signal may have a first frequency range.

At operation 402, an optional operation, the processing logic amplifies a second portion of the electrical signal to generate a second compensated portion of the electrical signal. In at least one embodiment, the second portion of the electrical signal may have a second frequency range.

At operation 403, the processing logic generates an optical signal based on a combination of the first compensated portion of the electrical signal and a second portion of the electrical signal.

At operation 404, the processing logic detects a photodetection current based on the optical signal. In at least one embodiment, the photodetection current is detected using a light-detection component, such as, for example, a photodiode.

At operation 405, the processing logic generates, using a transimpedance amplifier (TIA), an electrical feedback signal based on at least the photodetection current and a TIA gain value of the TIA. The electrical feedback signal may represent the signal strength (e.g., represented as the signal power, voltage, current, etc.) of the optical signal. In at least one embodiment, the electrical feedback signal is an amplified voltage signal. For example, the TIA may receive the photodetection current from the photodiode, convert the photodetection current to a voltage signal, and amplify the voltage signal (e.g., increase the power of the voltage signal relative to the photodetection current). Signal processing components including one or more of active circuit elements, passive circuit elements, or circuit logic elements may process the amplified voltage signal. In at least one embodiment, the signal strength is represented as a Root Mean Square (RMS) value. For example, the signal processing elements may determine an RMS voltage for the amplified voltage signal.

At operation 406, the processing logic determines one or more physical conditions associated with one or more components used to process the electrical and/or optical signal. For example, and in at least one embodiment, the processing logic determines a temperature of an electro-optical modulator (EOM). The processing logic may determine other physical conditions of the signal conditioning/processing components, such as light reflection or refraction.

At operation 407, the processing logic sets the TIA gain value to a first TIA gain value based on the photodetection current and the one or more physical conditions. In at least one embodiment, and as described above, one or more portions of the operation 407 for setting the TIA gain value is performed by active and/or passive circuit elements of a circuit (e.g., circuit 300) including, for example, one or more of amplifiers, resistors, capacitors, diodes, photodiodes, or the like. In at least one embodiment, and as described above, one or more portions of the operation 407 is performed by logic-based circuit elements such as logic gates, flip-flops, registers, microcontrollers, or microprocessors.

At operation 408, the processing logic updates the first compensated portion of the electrical signal based at least in part on the signal strength of the optical signal. In at least one embodiment, and as described above, one or more portions of the operation 408 for updating the first compensated portion of the electrical signal are performed by the interactions between passive and/or active circuit elements within a circuit, (e.g., circuit 300). In at least one embodiment, and as described above, one or more portions of the operation 408 are performed by logic-based circuit elements.

At operation 409, the processing logic receives an initial optical signal from a light-emitting component. In at least one embodiment, the initial optical signal can optically represent a portion of the information contained in the electrical signal.

At operation 410, the processing logic modulates the combination of the first compensated portion of the electrical signal and the second portion of the electrical signal onto the initial optical signal at an electro-optical modulator to generate the optical signal. In at least one embodiment, the electro-optical modulator is controlled by an electrical signal (e.g., the combined compensated signal of operation 403). The electro-optical modulator may optically couple to an optical source (e.g., an optical signal) and the electrical signal may cause the electro-optical modulator to encode information onto the optical signal by activating the electro-optical effect of the modulator at the cadence of the electrical signal.

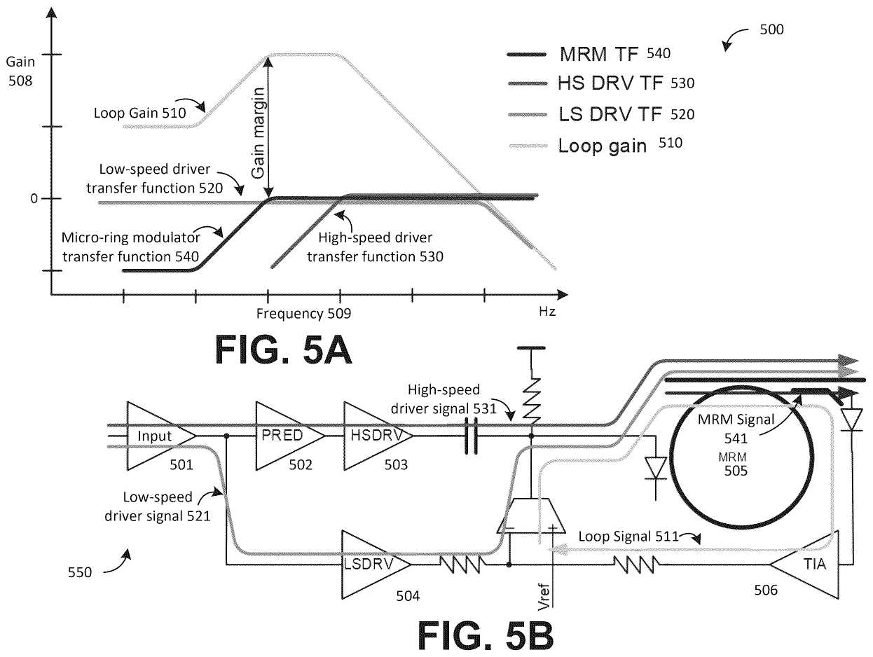

FIG. 5A is a graphical representation of gain values for various signals in a closed-loop or partially-closed loop electro-optical modulator driver in a high bandwidth scenario 500, according to at least one example embodiment. In at least one embodiment, the graphical representation can represent the same, or similar electro-optical modulator driver described with reference to FIG. 2, FIG. 3A, and/or FIG. 3B (e.g., EOM 210 or circuit 300, respectively). The graphical representation shows loop gain 510 (lightest gray), low-speed driver (LSDRV) transfer function (TF) 520 (medium gray), high-speed driver (HSDRV) TF 530 (dark gray), and micro-ring modulator (MRM) TF 540 (black). Loop gain 510, LSDRV TF 520, HSDRV TF 530, and MRM TF 540 are plotted as a function of gain 508 and frequency 509.

It can be appreciated that the low-speed driver transfer function 520 remains at a constant gain through most of the graphical representation for a high bandwidth scenario 500, before dropping off at relatively higher frequencies. In at least one embodiment, the frequency at which that the low-speed driver transfer function 520 begins to drop off is approximately 10 gigahertz (GHz).

FIG. 5B is a circuit representation 550 that corresponds to the graphical representation of FIG. 5A for a high-bandwidth scenario 500.

The loop signal 511 is shown in corresponding lightest gray, and can loop through the MRM 505 (such as electro-optical modulator 252 of FIG. 2 or micro-ring EOM 331 of FIG. 3) and the transimpedance amplifier (TIA) 506.

The low speed driver signal 521 is shown in corresponding medium gray, and passes from input 501 through LSDRV 504 (such as first gain module 241 of FIG. 2 or LOW-SPEED DRIVER 314 of FIG. 3B) and MRM 505.

The high speed driver signal 531 is shown in corresponding dark gray, and passes from input 501 through predriver 502 (such as input stage 310 of FIG. 3A or FIG. 3B), to HSDRV 503 (such as second gain module 246 of FIG. 2 or HIGH-SPEED DRIVER 312 of FIG. 3B) and MRM 505.

The MRM signal 541 is shown in corresponding black, and represents the signal that passes through the MRM 505.

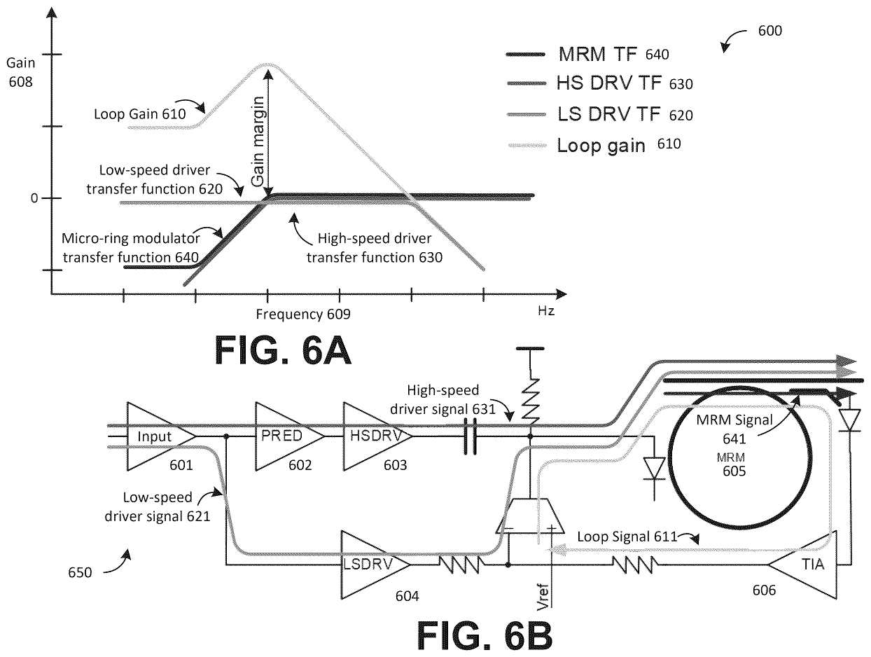

FIG. 6A is a graphical representation of gain values for various signals in a closed-loop or partially-closed loop electro-optical modulator driver in a medium-bandwidth scenario 600, according to at least one example embodiment. In at least one embodiment, the graphical representation can represent the same, or similar electro-optical modulator driver described with reference to FIG. 2, FIG. 3A, and/or FIG. 3B (e.g., EOM 210 or circuit 300, respectively). The graphical representation shows loop gain 610 (lightest gray), low-speed driver (LSDRV) transfer function (TF) 620 (medium gray), high-speed driver (HSDRV) TF 630 (dark gray), and micro-ring modulator (MRM) TF 640 (black). Loop gain 610, LSDRV TF 620, HSDRV TF 630, and MRM TF 640 are plotted as a function of gain 608 and frequency 609.

It can be appreciated that the low-speed driver transfer function 620 remains at a constant gain through most of the graphical representation for a medium-bandwidth scenario 600, before dropping off at a higher frequency. In at least one embodiment, the frequency at which that the low-speed driver transfer function 620 begins to drop off is approximately 1 gigahertz (GHz).

FIG. 6B is a circuit representation 650 that corresponds to the graphical representation of FIG. 6A for a high-bandwidth scenario 600. The circuit representation 650 can be the same as, or similar to the circuit representation 550 of FIG. 5 and is included for ease of reference to the medium-bandwidth scenario 600.

The loop signal 611 is shown in corresponding lightest gray, and can loop through the MRM 605 (such as electro-optical modulator 252 of FIG. 2 or micro-ring EOM 331 of FIG. 3) and the transimpedance amplifier (TIA) 606.

The low speed driver signal 621 is shown in corresponding medium gray, and passes from input 601 through LSDRV 604 (such as first gain module 241 of FIG. 2 or LOW-SPEED DRIVER 314 of FIG. 3B) and MRM 605.

The high speed driver signal 631 is shown in corresponding dark gray, and passes from input 601 through predriver 602 (such as input stage 310 of FIG. 3A or FIG. 3B), to HSDRV 603 (such as second gain module 246 of FIG. 2 or HIGH-SPEED DRIVER 312 of FIG. 3B) and MRM 605.

The MRM signal 641 is shown in corresponding black, and represents the signal that passes through the MRM 605.

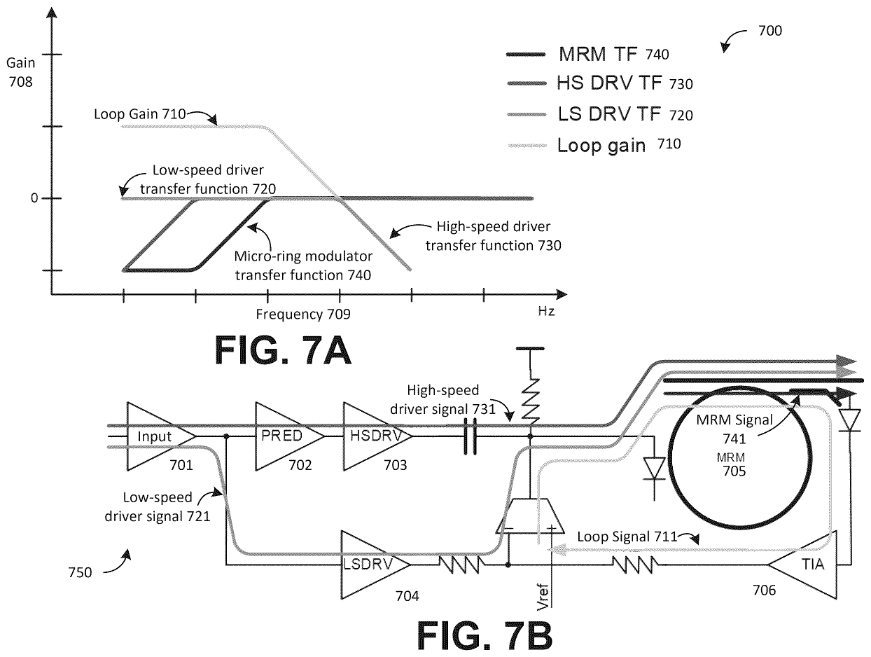

FIG. 7A is a graphical representation of gain values for various signals in a closed-loop or partially-closed loop electro-optical modulator driver in a low-bandwidth scenario 700, according to at least one example embodiment. In at least one embodiment, the graphical representation can represent the same, or similar electro-optical modulator driver described with reference to FIG. 2, FIG. 3A, and/or FIG. 3B (e.g., EOM 210 or circuit 300, respectively). The graphical representation shows loop gain 710 (lightest gray), low-speed driver (LSDRV) transfer function (TF) 720 (medium gray), high-speed driver (HSDRV) TF 730 (dark gray), and micro-ring modulator (MRM) TF 740 (black). Loop gain 710, LSDRV TF 720, HSDRV TF 730, and MRM TF 740 are plotted as a function of gain 708 and frequency 709.

It can be appreciated that the low-speed driver transfer function 720 remains at a constant gain through most of the graphical representation for a low-bandwidth scenario 700, before dropping off at relatively higher frequencies. In at least one embodiment, the frequency at which that the low-speed driver transfer function 720 begins to drop off is approximately 100 megahertz (MHz).

FIG. 7B is a circuit representation 750 that corresponds to the graphical representation of FIG. 7A for a high-bandwidth scenario 700. The circuit representation 750 can be the same as, or similar to the circuit representation 550 of FIG. 5 and the circuit representation 650 of FIG. 6, respectively, and is included for ease of reference to the low-bandwidth scenario 700.

The loop signal 711 is shown in corresponding lightest gray, and can loop through the MRM 705 (such as electro-optical modulator 252 of FIG. 2 or micro-ring EOM 331 of FIG. 3) and the transimpedance amplifier (TIA) 706.

The low speed driver signal 721 is shown in corresponding medium gray, and passes from input 701 through LSDRV 704 (such as first gain module 241 of FIG. 2 or LOW-SPEED DRIVER 314 of FIG. 3B) and MRM 705.

The high speed driver signal 731 is shown in corresponding dark gray, and passes from input 701 through predriver 702 (such as input stage 310 of FIG. 3A or FIG. 3B), to HSDRV 703 (such as second gain module 246 of FIG. 2 or HIGH-SPEED DRIVER 312 of FIG. 3B) and MRM 705.

The MRM signal 741 is shown in corresponding black, and represents the signal that passes through the MRM 705.

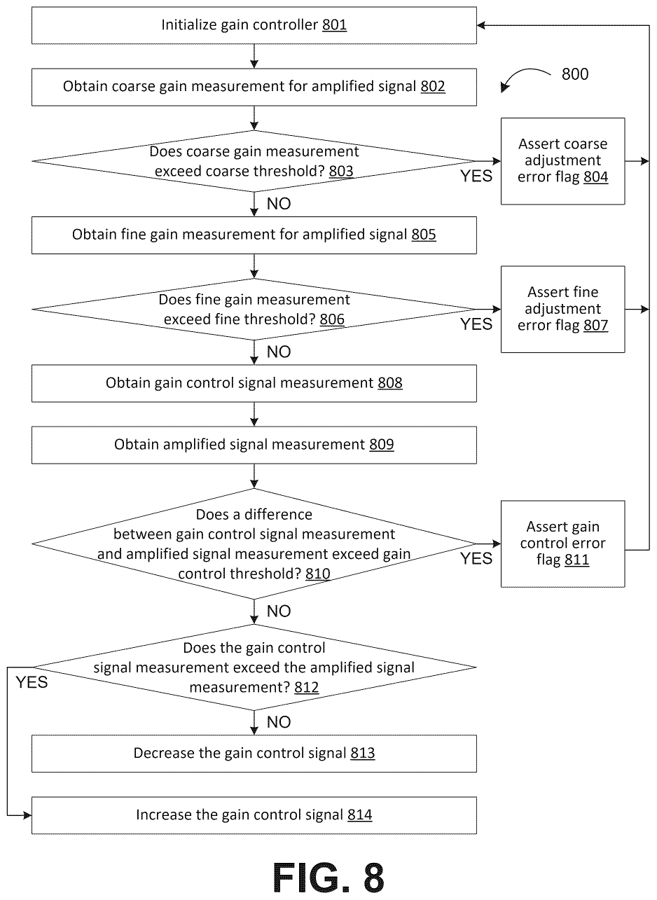

FIG. 8 is an example flow diagram of an example method 800 for controlling gain of an amplified signal in a closed-loop or partially-closed loop electro-optical modulator driver, according to at least one example embodiment. The method 800 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In at least one embodiment, one or more operations of the method 800 are performed by the processing circuitry 123 of FIG. 1. In at least one embodiment, one or more operations of the method 800 are performed by the closed-loop EOM driver 110 of FIG. 1. In at least one embodiment, one or more operations of the method 800 are performed by passive and/or active circuit elements. In at least one embodiment, one or more operations of the method 800 are performed by circuit logic elements (such as by the gain controller 350 of FIG. 3B). Although shown in a particular sequence or order, unless otherwise specified, the order of the processes may be modified. Thus, the illustrated embodiments should be understood only as examples, and the illustrated processes may be performed in a different order, and some processes may be performed in parallel. Additionally, one or more processes may be omitted in various embodiments. Thus, not all processes are required in every embodiment. Other process flows are possible.

At operation 801, processing logic performing the method 800 initializes the gain controller. In some embodiments, a coarse count and a fine count can be set to an initial value, such as zero. In some embodiments, the initial value can be an expected value for a given frequency. In some embodiments, some or all of the operation 801 can be repeated during the method 800 at various times. In some embodiments, the method 800 can be repeated at a regular interval by initiating the operation 801.

At operation 802, the processing logic obtains a coarse gain measurement for an amplified signal. The amplified signal can be output from the gain control module. The coarse gain measurement can be used to determine a broad frequency range (coarse measurement) of the amplified signal. In some embodiments, a frequency sweep can be performed based on a coarse measurement interval. In some embodiments, the coarse measurement interval can be reflected as a count that is compared to an output from an analog digital converter (ADC) signal of the amplified signal. In some embodiments, the gain of the amplified signal is controlled by the gain control module, while the source of the amplified signal is external to the gain control module. In some embodiments, the gain control module can obtain the coarse gain measurement.

At operation 803, the processing logic determines whether the coarse gain measurement exceeds a coarse threshold. In some embodiments, if the coarse gain measurement is greater than a coarse threshold, the processing logic can proceed to operation 804. In some embodiments, the coarse gain measurement can be an absolute value. That is, the coarse gain measurement can reflect that the amplified signal is below an expected value, or that the amplified signal is above the expected value. Within a certain range (e.g., plus or minus the coarse threshold), the method 800 can continue to operation 805.

At operation 804, responsive to determining the coarse gain measurement exceeds the coarse threshold, the processing logic can assert a coarse adjustment error flag. In some embodiments, the asserted coarse adjustment error flag can pause the method 800. In some embodiments, the asserted coarse adjustment error flag can cause the processing logic to perform additional operations (not illustrated). In some embodiments, the asserted coarse adjustment error flag can cause the processing logic to restart the method 800 at the operation 801. In some embodiments, the asserted coarse adjustment error flag can cause the processing logic to restart the method 800 at the operation 802.

At operation 805, responsive to determining the coarse gain adjustment does not exceed the coarse threshold, the processing logic can obtain a fine gain measurement for the amplified signal. In some embodiments, the fine gain measurement can be used to determine a more specific frequency range (fine measurement) within the broad frequency range (coarse measurement) determined at the operation 802. In some embodiments, a frequency sweep can be performed based on a fine measurement interval. In some embodiments, the fine measurement interval can be reflected as a count that is compared to an ADC output of the amplified signal.

At operation 806, the processing logic determines whether the fine gain measurement exceeds a fine threshold. In some embodiments, if the fine gain measurement is greater than a fine threshold, the processing logic can proceed to operation 807. In some embodiments, the fine gain measurement can be an absolute value. That is, the fine gain measurement can reflect that the amplified signal is below an expected value, or that the amplified signal is above the expected value. Within a certain range (e.g., plus or minus the fine threshold), the method 800 can continue to operation 808.

At operation 807, responsive to determining the fine gain measurement exceeds the fine threshold, the processing logic can assert a fine adjustment error flag. In some embodiments, the asserted fine adjustment error flag can pause the method 800. In some embodiments, the asserted fine adjustment error flag can cause the processing logic to perform additional operations (not illustrated). In some embodiments, the asserted fine adjustment error flag can cause the processing logic to restart the method 800 at the operation 801. In some embodiments, the asserted fine adjustment error flag can cause the processing logic to restart the method 800 at the operation 805.

At operation 808, responsive to determining the fine gain measurement does not exceed the fine threshold, the processing logic can obtain a gain control signal measurement. The gain control signal measurement can be a measurement of the gain control signal produced by the gain control module to control the gain of the amplified signal.

At operation 809, the processing logic can obtain an amplified signal measurement. In some embodiments, the operation 809 can be completed during the operation 805. In some embodiments, the operation 805 determines a narrow (e.g., “fine”) measurement range, and at the operation 809, the amplified signal measurement is obtained.

At operation 810, the processing logic can determine whether a difference between the gain control signal measurement and the amplified signal measurement exceeds a gain control threshold. If the difference between the gain control signal measurement and the amplified signal measurement exceeds the gain control threshold, the processing logic can proceed to operation 811. If the difference between the gain control signal measurement and the amplified signal does not exceed the gain control threshold, the processing logic can proceed to operation 812.

At operation 811, responsive to determining the difference between the gain control signal measurement and the amplified signal measurement exceeds the gain control threshold, the processing logic can assert a gain control error flag. In some embodiments, the asserted gain control error flag can pause the method 800. In some embodiments, the asserted gain control error flag can cause the processing logic to perform additional operations (not illustrated). In some embodiments, the asserted gain control error flag can cause the processing logic to restart the method 800 at the operation 801. In some embodiments, the asserted gain control error flag can cause the processing logic to restart the method 800 at any of the previous operations of the method 800 (e.g., operations 801-808).

At operation 812, responsive to determining the difference between the gain control signal measurement and the amplified signal measurement does not exceed the gain control threshold, the processing logic can determine whether the gain control signal measurement exceeds the amplified signal measurement.

At operation 813, responsive to determining the gain control signal measurement does not exceed the amplified signal measurement, the processing logic can decrease the gain control signal. In some embodiments, the amplified signal measurement can be based in part on standard, or expected amplified signal measurement (e.g., an amplified signal average value).

At operation 814, responsive to determining the gain control signal measurement exceeds the amplified signal measurement, the processing logic can increase the gain control signal.

### Computer Systems

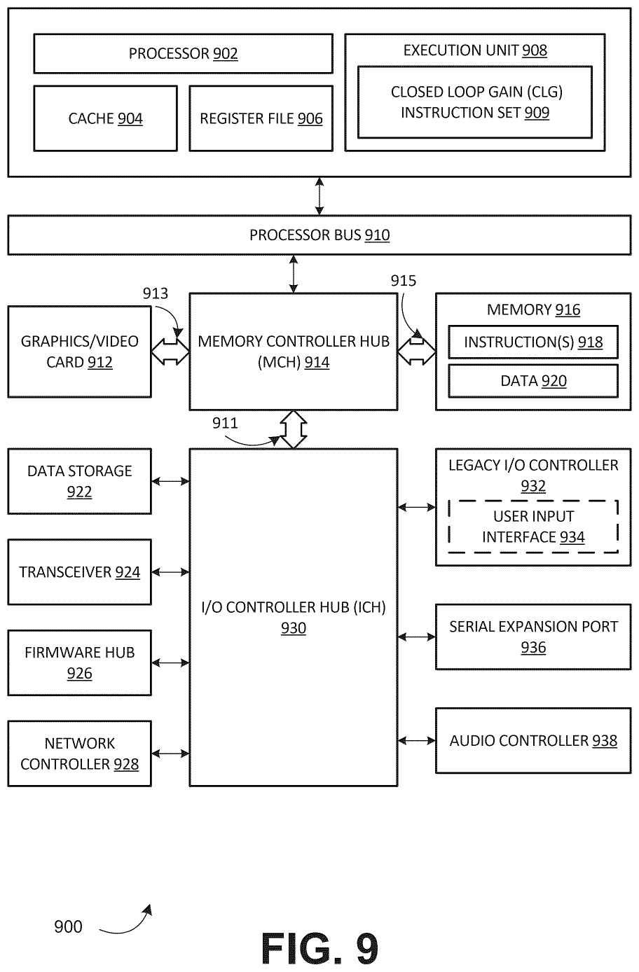

FIG. 9 is a block diagram illustrating an exemplary computer system, such as computer system 900, which may be a system with interconnected devices and components, a system-on-a-chip (SOC), or some combination thereof, according to aspects of the disclosure. In at least one embodiment, computer system 900 may include, without limitation, a component, such as a processor 902, to employ execution units including logic to perform algorithms for process data, in accordance with the present disclosure, such as in the embodiments described herein. In at least one embodiment, computer system 900 may include processors, such as PENTIUM® Processor family, Xcon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 900 may execute a version of WINDOWS' operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (PDAs), and handheld PCs. In at least one embodiment, embedded applications may include a microcontroller, a digital signal processor (DSP), a system on a chip, network computers (NetPCs), set-top boxes, network hubs, wide area network (WAN) switches, or any other system that may perform one or more instructions in accordance with at least one embodiment.

In at least one embodiment, computer system 900 may include, without limitation, processor 902 that may include, without limitation, one or more execution units 908 to perform operations according to techniques described herein. In at least one embodiment, computer system 900 is a single-processor desktop or server system, but in another embodiment, the computer system 900 may be a multiprocessor system. In at least one embodiment, processor 902 may include, without limitation, a complex instruction set computer (CISC) microprocessor, a reduced instruction set computing (RISC) microprocessor, a very long instruction word (VLIW) microprocessor, a processor implementing a combination of instruction sets, or any other processor device, such as a digital signal processor, for example. In at least one embodiment, processor 902 may be coupled to a processor bus 910 that may transmit data signals between processor 902 and other components in computer system 900.

In at least one embodiment, processor 902 may include, without limitation, a Level-1 (L1) internal cache memory (cache) cache 904. In at least one embodiment, processor 902 may have a single internal cache or multiple levels of internal cache. In at least one embodiment, the cache memory may reside external to processor 902. Other embodiments may also include a combination of both internal and external caches depending on particular implementation and needs. In at least one embodiment, register file 906 may store different types of data in various registers, including and without limitation, integer registers, floating-point registers, status registers, and instruction pointer registers.

In at least one embodiment, an execution unit 908, including and without limitation, logic to perform integer and floating-point operations, also reside in processor 902. In at least one embodiment, processor 902 may also include a microcode (ucode) read-only memory (ROM) that stores microcode for certain macro instructions. In at least one embodiment, execution unit 908 may include logic to handle a closed loop gain instruction set 909. In at least one embodiment, by including closed loop gain instruction set 909 in an instruction set of a general-purpose processor, such as processor 902, along with associated circuitry to execute instructions, operations used by many multimedia applications may be performed using packed data in a general-purpose processor, such as processor 902. In one or more embodiments, many multimedia applications may be accelerated and executed more efficiently by using the full width of a processor's data bus for performing operations on packed data, which may eliminate the need to transfer smaller units of data across the processor's data bus to perform one or more operations one data element at a time.

In at least one embodiment, execution unit 908 may also be used in microcontrollers, embedded processors, graphics devices, DSPs, and other types of logic circuits. In at least one embodiment, computer system 900 may include, without limitation, a memory 916. In at least one embodiment, memory 916 may be implemented as a Dynamic Random Access Memory (DRAM) device, a Static Random Access Memory (SRAM) device, a flash memory device, or other memory devices. In at least one embodiment, memory 916 may store instruction(s) 918 and/or data 920 represented by data signals that may be executed by processor 902.

In at least one embodiment, the system logic chip may be coupled to processor bus 910 and memory 916. In at least one embodiment, the system logic chip may include, without limitation, a memory controller hub (MCH), such as MCH 914, and processor 902 may communicate with MCH 914 via processor bus 910. In at least one embodiment, MCH 914 may provide a high bandwidth memory path 915 to memory 916 for instruction and data storage and for storage of graphics commands, data, and textures. In at least one embodiment, MCH 914 may direct data signals between processor 902, memory 916, and other components in computer system 900 and bridge data signals between processor bus 910, memory 916, and a system I/O 911. In at least one embodiment, a system logic chip may provide a graphics port for coupling to a graphics controller. In at least one embodiment, MCH 914 may be coupled to memory 916 through a high bandwidth memory path 915, and graphics/video card 912 may be coupled to MCH 914 through an Accelerated Graphics Port (AGP) interconnect 913.

In at least one embodiment, computer system 900 may use the system I/O 911 that is a proprietary hub interface bus to couple the MCH 914 to I/O controller hub (ICH), such as ICH 930. In at least one embodiment, ICH 930 may provide direct connections to some I/O devices via a local I/O bus. In at least one embodiment, a local I/O bus may include, without limitation, a high-speed I/O bus for connecting peripherals to memory 916, chipset, and processor 902. Examples may include, without limitation, data storage 922, a transceiver 924, a firmware hub (flash BIOS) 926, a network controller 928, a legacy I/O controller 932 containing a user input interface 934, a serial expansion port 936, such as Universal Serial Bus (USB), and an audio controller 938. In at least one embodiment, data storage 922 may include a hard disk drive, a floppy disk drive, a CD-ROM device, a flash memory device, or other mass storage devices.

In at least one embodiment, FIG. 9 illustrates a computer system 900, which includes interconnected hardware devices or “chips,” whereas, in other embodiments, FIG. 9 may illustrate an exemplary System on a Chip (SoC). In at least one embodiment, devices may be interconnected with proprietary interconnects, standardized interconnects (e.g., PCIe), or some combination thereof. In at least one embodiment, one or more components of computer system 900 are interconnected using compute express link (CXL) interconnects.

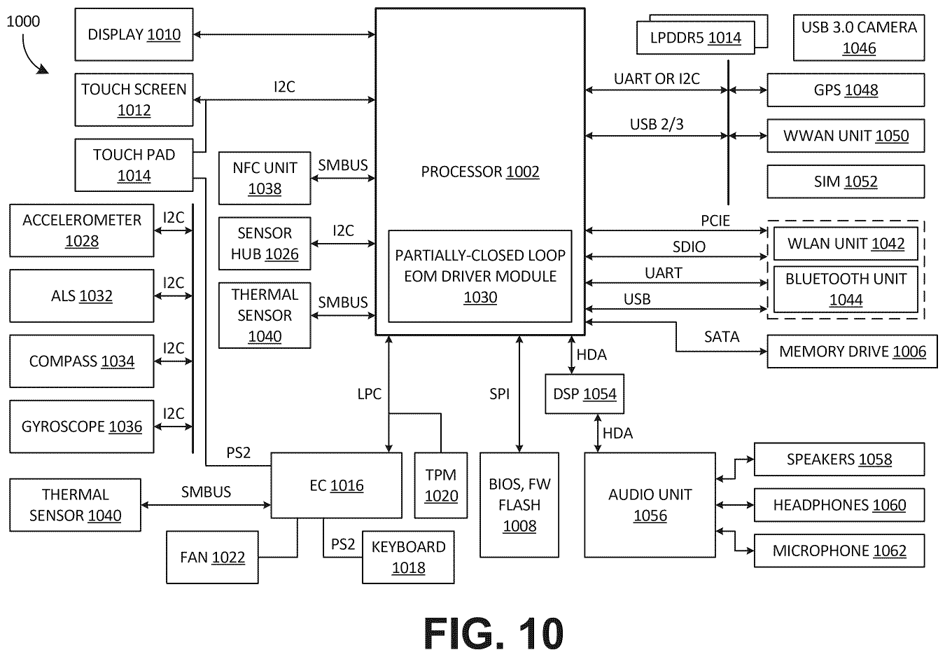

FIG. 10 is a block diagram illustrating an electronic device 1000 for utilizing a processor 1002, according to aspects of the disclosure. In at least one embodiment, electronic device 1000 may be, for example, and without limitation, a notebook, a tower server, a rack server, a blade server, a laptop, a desktop, a tablet, a mobile device, a phone, an embedded computer, or any other suitable electronic device.

In at least one embodiment, electronic device 1000 may include, without limitation, processor 1002 communicatively coupled to any suitable number or kind of components, peripherals, modules, or devices. In at least one embodiment, processor 1002 coupled using a bus or interface, such as an I2C bus, a System Management Bus (SMBus), a Low Pin Count (LPC) bus, a Serial Peripheral Interface (SPI), a High Definition Audio (HDA) bus, a Serial Advance Technology Attachment (SATA) bus, a Universal Serial Bus (USB) (including USB 1.0/1/1, USB 2.0, USB 3.0/3.1 Gen1/3.1 Gen2, and USB4), or a Universal Asynchronous Receiver/Transmitter (UART) bus. In at least one embodiment, FIG. 10 illustrates a system, which includes interconnected hardware devices or “chips,” whereas in other embodiments, FIG. 10 may illustrate an exemplary System on a Chip (SoC). In at least one embodiment, devices illustrated in FIG. 10 may be interconnected with proprietary interconnects, standardized interconnects (e.g., PCIe), or some combination thereof. In at least one embodiment, one or more components of FIG. 10 are interconnected using compute express link (CXL) interconnects.

In at least one embodiment, FIG. 10 may include a display 1010, a touch screen 1012, a touch pad 1014, a Near Field Communications unit (NFC) 1038, a sensor hub 1026, a thermal sensor 1040, an Express Chipset (EC), such as EC 1016, a Trusted Platform Module (TPM), such as TPM 1020, BIOS/firmware (FW)/flash memory, such as BIOS, FW Flash 1008, a DSP 1054, a memory drive 1006 such as a Solid State Disk (SSD) or a Hard Disk Drive (HDD), a wireless local area network unit (WLAN), such as WLAN unit 1042, a Bluetooth unit 1044, a Wireless Wide Area Network unit (WWAN), such as WWAN unit 1050, a Global Positioning System (GPS) 1048, a camera (USB 3.0 camera) 1046, such as a USB 3.0 camera, and/or a Low Network bandwidth Double Data Rate (LPDDR) memory unit, such as LPDDR5 1004 implemented in, for example, LPDDR5 standard. These components may each be implemented in any suitable manner.

In at least one embodiment, other components may be communicatively coupled to processor 1002 through the components discussed above. In at least one embodiment, processor 1002 may include partially-closed-loop EOM driver module 1030. In at least one embodiment, an accelerometer 1028, Ambient Light Sensor (ALS), such as ALS 1032, compass 1034, and a gyroscope 1036 may be communicatively coupled to sensor hub 1026. In at least one embodiment, thermal sensor 1040, a fan 1022, a keyboard 1018, and a touch pad 1014 may be communicatively coupled to EC 1016. In at least one embodiment, speakers 1058, headphones 1060, and microphone 1062 may be communicatively coupled to an audio unit 1056 which may, in turn, be communicatively coupled to DSP 1054. In at least one embodiment, audio unit 1056 may include, for example, and without limitation, an audio coder/decoder (codec) and a class-D amplifier. In at least one embodiment, a subscriber identification module (SIM) card, such as SIM 1052 may be communicatively coupled to WWAN unit 1050. In at least one embodiment, components such as WLAN unit 1042 and Bluetooth unit 1044, as well as WWAN unit 1050 may be implemented in a Next Generation Form Factor (NGFF).

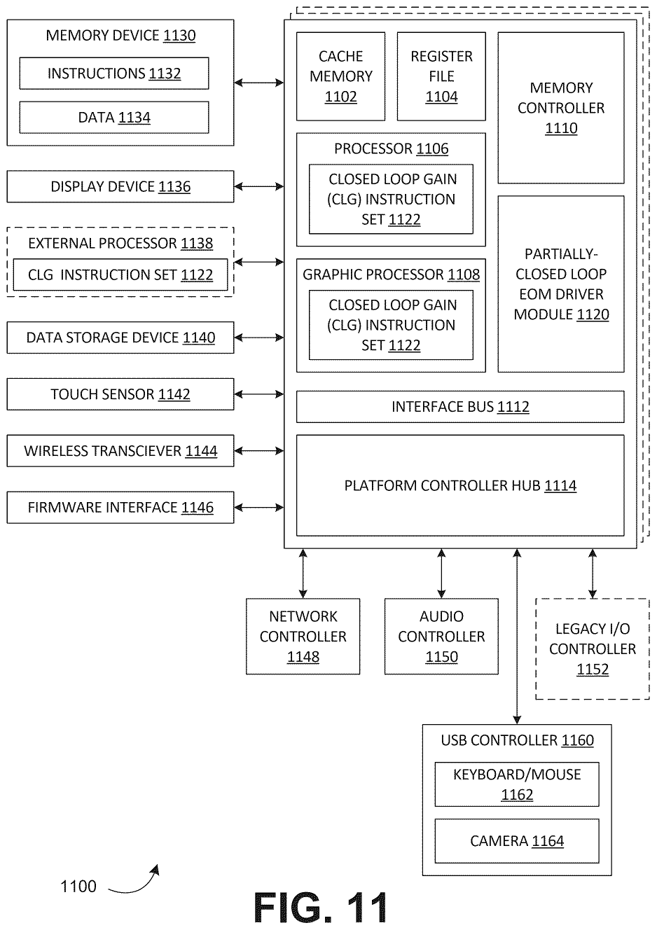

FIG. 11 is a block diagram of a processing system 1100, according to aspects of the disclosure. In at least one embodiment, the processing system 1100 includes cache memory 1102, register file 1104, processors 1106, graphics processors 1108, memory controller 1110, interface bus 1112, platform controller hub 1114, and partially-closed-loop EOM driver module 1120. Processing system 1100 may be a single processor desktop system, a multiprocessor workstation system, or a server system having a large number of processors 1106 or graphics processors 1108. In at least one embodiment, the processing system 1100 is a processing platform incorporated within a system-on-a-chip (SoC) integrated circuit for use in mobile, handheld, or embedded devices.

In at least one embodiment, the processing system 1100 may include, or be incorporated within a server-based gaming platform, a game console, including a game and media console, a mobile gaming console, a handheld game console, or an online game console. In at least one embodiment, the processing system 1100 is a mobile phone, smart phone, tablet computing device, or mobile Internet device. In at least one embodiment, the processing system 1100 may also include, couple with, or be integrated within, a wearable device, such as a smart watch wearable device, smart eyewear device, augmented reality device, or virtual reality device. In at least one embodiment, the processing system 1100 is a television or set-top box device having one or more processors 1106 and a graphical interface generated by one or more graphics processors 1108.

In at least one embodiment, one or more processors 1106 each include one or more of the processor cores to process instructions which, when executed, perform operations for system and user software. In at least one embodiment, one or more processors 1106 and/or one or more graphics processors may be configured to process a portion of the closed loop gain instruction set 1122. In at least one embodiment, closed loop gain instruction set 1122 may facilitate Complex Instruction Set Computing (CISC), Reduced Instruction Set Computing (RISC), or computing via a Very Long Instruction Word (VLIW). In at least one embodiment, processor cores may each process a different instruction set from closed loop gain instruction set 1122, which may include instructions to facilitate emulation of other instruction sets (not illustrated). In at least one embodiment, processor cores may also include other processing devices, such as a Digital Signal Processor (DSP).

In at least one embodiment, processors 1106 includes cache memory 1102. In at least one embodiment, processors 1106 may have a single internal cache or multiple levels of internal cache. In at least one embodiment, cache memory 1102 is shared among various components of processors 1106. In at least one embodiment, processors 1106 also uses an external cache (e.g., a Level-3 (L3) cache or Last Level Cache (LLC)) (not illustrated), which may be shared among processor cores using known cache coherency techniques. In at least one embodiment, register file 1104 is additionally included in processors 1106, which may include different types of registers for storing different types of data (e.g., integer registers, floating-point registers, status registers, and an instruction pointer register). In at least one embodiment, register file 1104 may include general-purpose registers or other registers.

In at least one embodiment, one or more processors 1106 are coupled with one or more interface bus 1112 to transmit communication signals such as address, data, or control signals between processor cores and other components in processing system 1100. In at least one embodiment, interface bus 1112, in one embodiment, may be a processor bus, such as a version of a Direct Media Interface (DMI) bus. In at least one embodiment, interface bus 1112 is not limited to a DMI bus, and may include one or more Peripheral Component Interconnect buses (e.g., PCI, PCI Express), memory busses, or other types of interface busses. In at least one embodiment, processors 1106 include an integrated memory controller (e.g., memory controller 1110) and a platform controller hub 1114 (PCH). In at least one embodiment, memory controller 1110 facilitates communication between a memory device and other components of the processing system 1100, while platform controller hub 1114 provides connections to I/O devices via a local I/O bus.

In at least one embodiment, the memory device 1130 may be a dynamic random access memory (DRAM) device, a static random access memory (SRAM) device, a flash memory device, a phase-change memory device, or some other memory device having suitable performance to serve as process memory. In at least one embodiment, the memory device 1130 may operate as system memory for processing system 1100 to store instructions 1132 and data 1134 for use when one or more processors 1106 executes an application or process. In at least one embodiment, memory controller 1110 also optionally couples with an external processor 1138, which may communicate with one or more graphics processors 1108 in processors 1106 to perform graphics and media operations. In at least one embodiment, a display device 1136 may connect to processors 1106. In at least one embodiment, the display device 1136 may include one or more of an internal display device, as in a mobile electronic device or a laptop device, or an external display device attached via a display interface (e.g., DisplayPort, etc.). In at least one embodiment, display device 1136 may include a head-mounted display (HMD) such as a stereoscopic display device for use in virtual reality (VR) applications or augmented reality (AR) applications.

In at least one embodiment, the platform controller hub 1114 enables peripherals to connect to memory device 1130 and processors 1106 via a high-speed I/O bus. In at least one embodiment, I/O peripherals include, but are not limited to, a data storage device 1140 (e.g., hard disk drive, flash memory, etc.), a touch sensor 1142, a wireless transceiver 1144, firmware interface 1146, a network controller 1148, or an audio controller 1150.

In at least one embodiment, the data storage device 1140 may connect via a storage interface (e.g., SATA) or via a peripheral bus, such as a Peripheral Component Interconnect bus (e.g., PCI, PCI Express). In at least one embodiment, touch sensor 1142 may include touch screen sensors, pressure sensors, or fingerprint sensors. In at least one embodiment, wireless transceiver 1144 may be a Wi-Fi transceiver, a Bluetooth transceiver, or a mobile network transceiver such as a 3G, 4G, or Long Term Evolution (LTE) transceiver. In at least one embodiment, firmware interface 1146 enables communication with system firmware and may be, for example, a unified extensible firmware interface (UEFI). In at least one embodiment, the network controller 1148 may enable a network connection to a wired network. In at least one embodiment, a high-performance network controller (not illustrated) couples with interface bus 1112. In at least one embodiment, audio controller 1150 may be a multi-channel high-definition audio controller. In at least one embodiment, the processing system 1100 includes an optional legacy I/O controller 1152 for coupling legacy (e.g., Personal System-2 (PS/2)) devices to the processing system 1100. In at least one embodiment, the platform controller hub 1114 may also connect to one or more Universal Serial Bus (USB) controllers, such as USB controller 1160 to connect input devices, such as a keyboard and mouse combination (keyboard/mouse 1162), a camera 1164, or other USB input devices.

In at least one embodiment, an instance of memory controller 1110 and platform controller hub 1114 may be integrated into a discreet external graphics processor, such as external processor 1138. In at least one embodiment, the platform controller hub 1114 and/or memory controller 1110 may be external to one or more processors 1106. For example, In at least one embodiment, the processing system 1100 may include an external memory controller (e.g., memory controller 1110) and the platform controller hub 1114, which may be configured as a memory controller hub and peripheral controller hub within a system chipset that is in communication with the processors 1106.

Other variations are within the spirit of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. The term “connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. Use of the term “set” (e.g., “a set of items”) or “subset,” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and corresponding set may be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., may be either A or B or C, or any nonempty subset of a set of A and B and C. For instance, in an illustrative example of a set having three members, conjunctive phrases “at least one of A, B, and C” and “at least one of A, B, and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). A plurality is at least two items but may be more when so indicated either explicitly or by context. Further, unless stated otherwise or otherwise clear from context, the phrase “based on” means “based at least in part on” and not “based solely on.”

Operations of processes described herein may be performed in any suitable order unless otherwise indicated herein or otherwise clearly contradicted by context. In at least one embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. A set of non-transitory computer-readable storage media, In at least one embodiment, includes multiple non-transitory computer-readable storage media and one or more of individual non-transitory storage media of multiple non-transitory computer-readable storage media lacks all of the code while multiple non-transitory computer-readable storage media collectively store all of the code. In at least one embodiment, executable instructions are executed such that different instructions are executed by different processors—for example, a non-transitory computer-readable storage medium stores instructions, and a main central processing unit (CPU) executes some of the instructions while a graphics processing unit (GPU) executes other instructions. In at least one embodiment, different components of a computer system have separate processors, and different processors execute different subsets of instructions.

Accordingly, In at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples or exemplary language (e.g., “such as”) provided herein is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, the terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other but yet still co-operate or interact with each other.

Unless specifically stated otherwise, it may be appreciated that throughout specification terms such as “processing,” “computing,” “calculating,” “determining,” or like, refer to action and/or processes of a computer or computing system or similar electronic computing device, that manipulates and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. As non-limiting examples, a “processor” may be a CPU or a GPU. A “computing platform” may include one or more processors. As used herein, “software” processes may include, for example, software and/or hardware entities that perform work over time, such as tasks, threads, and intelligent agents. Also, each process may refer to multiple processes for carrying out instructions in sequence or in parallel, continuously, or intermittently. The terms “system” and “method” are used herein interchangeably insofar as a system may embody one or more methods, and methods may be considered a system.

In the present document, references may be made to obtaining, acquiring, receiving, or inputting analog or digital data into a subsystem, computer system, or computer-implemented machine. Obtaining, acquiring, receiving, or inputting analog and digital data may be accomplished in a variety of ways, such as by receiving data as a parameter of a function call or a call to an application programming interface. In some implementations, the process of obtaining, acquiring, receiving, or inputting analog or digital data may be accomplished by transferring data via a serial or parallel interface. In another implementation, the process of obtaining, acquiring, receiving, or inputting analog or digital data may be accomplished by transferring data via a computer network from providing entity to acquiring entity. References may also be made to providing, outputting, transmitting, sending, or presenting analog or digital data. In various examples, the process of providing, outputting, transmitting, sending, or presenting analog or digital data may be accomplished by transferring data as an input or output parameter of a function call, a parameter of an application programming interface, or an interprocess communication mechanism.

Although the discussion above sets forth example implementations of described techniques, other architectures may be used to implement described functionality and are intended to be within the scope of this disclosure. Furthermore, although specific distributions of responsibilities are defined above for purposes of discussion, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system comprising:
a first gain module to process a first portion of an electrical signal to generate a first compensated portion of the electrical signal, the first portion of the electrical signal having a first frequency range;
an optical module to generate an optical signal based on a combination of the first compensated portion of the electrical signal and a second portion of the electrical signal having a second frequency range that is higher than the first frequency range; and
a feedback module to provide, to the first gain module, an electrical feedback signal based at least in part on a signal strength of the optical signal, wherein the first gain module is to update the first compensated portion of the electrical signal based on the electrical feedback signal.

2. The system of claim 1, further comprising:
a second gain module to process the second portion of the electrical signal having the second frequency range to generate a second compensated portion of the electrical signal, wherein the optical module is to generate the optical signal based on the first compensated portion of the electrical signal and the second compensated portion of the electrical signal.

3. The system of claim 2, wherein the first gain module comprises a low-pass frequency filter to filter out the second portion of the electrical signal, and wherein the second gain module comprises a high-pass frequency filter to filter out the first portion of the electrical signal.

4. The system of claim 2, wherein the first gain module comprises a first driver that is direct current (DC)-coupled to the electrical signal, and wherein the second gain module comprises a second driver that is alternating current (AC)-coupled to the electrical signal.

5. The system of claim 2, further comprising: a delay component coupled at least to a first output of the first gain module or a second output of the second gain module.

6. The system of claim 1, wherein the first gain module generates the first compensated portion by amplifying the first portion of the electrical signal by a first gain value, wherein the first gain value is determined based at least in part on the electrical feedback signal.

7. The system of claim 1, wherein the feedback module comprises:
a photodiode to generate a detecting current based on the optical signal; and
a transimpedance amplifier (TIA) coupled to the photodiode to convert the detecting current into a voltage signal and amplify the voltage signal by a TIA gain value to generate an amplified voltage signal, wherein the amplified voltage signal is used to generate the electrical feedback signal.

8. The system of claim 7, further comprising:
a memory; and
one or more processing devices coupled to the memory and the feedback module, the one or more processing devices to:
determine, using the feedback module, a first signal strength of the optical signal;
determine one or more first physical conditions of the system; and
set the TIA gain value to a first TIA gain value based on the first signal strength of the optical signal and the one or more first physical conditions of the system.

9. The system of claim 1, wherein the optical module comprises:
a light-emitting component to generate an initial optical signal; and
an electro-optical modulator optically coupled to the light-emitting component, the electro-optical modulator to modulate the combination of the first compensated portion of the electrical signal and the second portion of the electrical signal onto the initial optical signal and generate the optical signal.

10. The system of claim 9, wherein the electro-optical modulator comprises a ring resonator.

11. The system of claim 1, wherein the electrical signal comprises a frequency range from 0 hertz (Hz) to approximately 50 gigahertz (GHz), and wherein the first frequency range comprises 0 Hz to approximately 10 megahertz.

12. The system of claim 1, wherein the electrical signal comprises a frequency range from 0 hertz (Hz) to approximately 50 gigahertz (GHz), and wherein the first frequency range comprises 0 Hz to approximately 1 GHz.

13. A method comprising:
amplifying a first portion of an electrical signal to generate a first compensated portion of the electrical signal, the first portion of the electrical signal having a first frequency range;
generating an optical signal based on a combination of the first compensated portion of the electrical signal and a second portion of the electrical signal having a second frequency range that is higher than the first frequency range; and
updating the first compensated portion of the electrical signal based at least in part on a signal strength of the optical signal.

14. The method of claim 13, further comprising:
amplifying the second portion of the electrical signal to generate a second compensated portion of the electrical signal, wherein the optical signal is generated based on a combination of the first compensated portion of the electrical signal and the second compensated portion of the electrical signal.

15. The method of claim 14, further comprising:
passing the electrical signal through a low-pass frequency filter to generate the first portion of the electrical signal; and
passing the electrical signal through a high-pass frequency filter to generate the second portion of the electrical signal.

16. The method of claim 14, further comprising:
amplifying the first portion of the electrical signal is performed using a first driver that is direct current (DC)-coupled to the electrical signal; and
amplifying the second portion of the electrical signal using a second driver that is alternating current (AC)-coupled to the electrical signal.

17. The method of claim 14, further comprising:
delaying at least one of the first portion of the electrical signal or the second portion of the electrical signal.

18. The method of claim 13, further comprising:
detecting a photodetection current based on the optical signal using a light-detecting component; and
generating, using a transimpedance amplifier (TIA), an electrical feedback signal based on at least the photodetection current and a TIA gain value of the TIA, wherein the electrical feedback signal represents the signal strength of the optical signal.

19. The method of claim 18, wherein generating the electrical feedback signal comprises:
determining one or more physical conditions associated with one or more components; and
setting the TIA gain value to a first TIA gain value based on the photodetection current and the one or more physical conditions.

20. The method of claim 13, wherein generating the optical signal comprises:
receiving an initial optical signal from a light-emitting component; and
modulating the combination of the first compensated portion of the electrical signal and the second portion of the electrical signal onto the initial optical signal at an electro-optical modulator to generate the optical signal.
